(19) United States
(12) Patent Application Publication
(10) Pub. No.: US 2009/0002084 A1
(43) Pub. Date: Jan. 1, 2009

(54) Oscillator

(76) Inventors: Akira Inoue, Osaka (JP); Kouji Katayama, Nara (JP); Takeshi Takagi, Kyoto (JP)

Correspondence Address: MCDERMOTT WILL & EMERY LLP, 600 13TH STREET, NW, WASHINGTON, DC, 20005-3096, US

(21) Appl. No.: 11/658,615

(22) PCT Filed: Jul. 13, 2005
(86) PCT No.: PCT/JP2005/012933

§ 371 Date: Jan. 26, 2007

(30) Foreign Application Priority Data
Jul. 28, 2004 (JP) 2004-220219

(51) Int. Cl. H03B 5/12

(52) U.S. Cl. 331/108 A

(57) ABSTRACT

In an oscillator of the present invention, each of field-effect transistors (12) and (13) contained as amplifier elements is a buried-channel transistor including: a body region formed on a semiconductor substrate, a source region and a drain region formed on the body region and having a different conductivity type from that of the body region, a buried channel layer formed between the source region and the drain region, and a gate electrode formed above the buried channel layer with a gate insulating film interposed therebetween, wherein body terminals (b12) and (b13) electrically connected to the body region are connected to a power supply wire to which a power supply potential (Vdd) is applied.

### TECHNICAL FIELD

The present invention relates to an oscillator comprising a field-effect transistor (MOSFET) as a constituent element.

### BACKGROUND ART

In recent years, mobile telephones and short-range wireless communication have been in widespread use. The transmitters and receivers for these types of communication networks require an oscillator as an essential key component. In order to realize an oscillator particularly with advanced functions at low cost, semiconductor integrated circuits, in which transistors, inductors, capacitors, and resistors are integrated on a semiconductor substrate, are used. A semiconductor integrated circuit containing such an oscillator circuit has been constructed using a Bi-CMOS process, which can integrate bipolar transistors and CMOS circuits, so that the integrated circuit can be constructed by an analog circuit portion being comprised of the bipolar transistors and a digital circuit portion such as memories being comprised of CMOS devices. However, as miniaturization advances due to the development of semiconductor processing technology, field-effect transistors have been able to achieve high-frequency characteristics comparable to those of the bipolar transistors. Thus, an analog CMOS device that employs field-effect transistors also for its analog circuit portion has recently attracted attention (for example, see Non-patent Reference 1). The analog CMOS device has the advantage of being low cost because the fabrication process is simpler than that for the Bi-CMOS.

A conventional example of a cross-coupled nMOSFET differential oscillator is shown in FIG. 21(a) as an example in which field-effect transistors are used for an oscillator. In this example, inductors 30 and 31 and capacitors 33 and 34 form a resonator (LC resonator), and a pair of surface-channel nMOSFETs 10 and 11 that are differentially connected form an amplifier. Spiral inductors are generally used for the inductors 30 and 31. MOS capacitors or MIM (metal insulator metal) capacitors are used for the capacitors 33 and 34. Reference characters Vdd and Vout denote power supply voltage and oscillation output signal, respectively. FIG. 21(d) shows a cross-coupled nMOSFET differential oscillator in a more general fashion. The resonant circuit portion may be configured by various configurations, so the resonant circuit portion here is represented by a LC resonant circuit 37. In this oscillator, the oscillation frequency is determined by the resonant frequency of the LC resonant circuit 37, and the nMOSFETs 10 and 11 that are differentially connected so as to compensate the loss in the LC resonant circuit 37 operate as an amplifier. The operating current of the circuit is determined by a current source 36. Likewise, a conventional example of a cross-coupled pMOSFET differential oscillator that uses surface-channel pMOSFETs as the amplifying transistors is shown FIG. 21(b). Also, a more general cross-coupled pMOSFET differential oscillator is shown in FIG. 21(e).

As shown in FIG. 21(c), a cross-coupled CMOS differential oscillator using surface-channel nMOSFETs and surface-channel pMOSFETs is also used. In this example, an inductor 32 and a capacitor 35 form a resonator (LC resonator), and surface-channel nMOSFETs 10 and 11 and pMOSFET 20 and 21 form an amplifier. More generally, a cross-coupled CMOS differential oscillator can be realized by the configuration as shown in FIG. 21(f).

As illustrated in FIGS. 21(a) and (d) and FIGS. 21(b) and (e), in a cross-coupled differential oscillator that is comprised of transistors of single polarity (nMOSFETs only or pMOSFETs only), the maximum voltage amplitude is 2×Vdd, where Vdd is a power supply voltage. As illustrated in FIGS. 21(c) and (f), although the cross-coupled CMOS differential oscillator has the advantage of higher current utilization efficiency than those in which the oscillator is comprised of MOSFETs of a single polarity only, such as nMOSFETs only or pMOSFETs only, it also has the disadvantage of the maximum voltage amplitude being Vdd. These oscillators using field-effect transistors have been used as conventional devices.

Other examples of the oscillators using field-effect transistors are shown in FIGS. 22 to 24. FIG. 22 includes circuit diagrams illustrating circuit configurations of conventional three-stage single-end ring oscillators, in which FIG. 22(a) illustrates a configuration that uses nMOSFETs, FIG. 22(b) illustrates a configuration that uses pMOSFETs, and FIG. 22(c) illustrates a configuration that uses nMOSFETs and pMOSFETs. In FIG. 22, reference characters MN1 to MN3 denote nMOSFETs. Reference characters MP1 to MP3 denote pMOSFETs. Reference characters C1 to C3 denote capacitors. Reference characters R1 to R3 denote resistors. Although the example of FIG. 22a illustrates three-stage single-end type in which the number of stages of the transistors is three stages, it is sufficient that the number of stages of the transistors should be an odd number; commonly used are three stages or five stages in many cases.

FIG. 23 includes circuit diagrams illustrating circuit configurations of conventional differential ring oscillators, in which FIG. 23(a) illustrates a configuration that uses nMOSFETs, FIG. 23(b) illustrates a configuration that uses pMOSFETs, and FIG. 23(c) illustrates a configuration that uses nMOSFETs and pMOSFETs. In FIG. 23, reference characters MN1 to MN6 denote nMOSFETs. Reference characters MP1 to MP6 denote pMOSFETs. Reference characters R1 to R6 denote resistors. Reference characters 11 to 13 denote current sources. Although the examples of FIG. 23 illustrate differential three-stage ring oscillators in which the number of stages of transistor pairs is three stages, oscillation occurs as long as the number of stages of the transistor be such that the total number of inversions in the loop is an odd number. Accordingly, in the case of differential type, the number of stages of the ring oscillator may be either an odd number or an even number, and the number of stages is determined from various requirements such as speed or power consumption, although three to five stages are generally used in many cases.

FIGS. 24(a) and (b) are circuit diagrams each illustrating a circuit configuration of a conventional Colpitts oscillator. FIG. 24(a) illustrates a configuration that uses an nMOSFET, and FIG. 24(b) illustrates a configuration that uses a pMOSFET. Reference character MN1 denotes an nMOSFET. Reference character MP1 denotes a pMOSFET. Reference character L1 denotes an inductor. Reference characters C1 and C2 denote capacitors. Reference character 11 denotes a current source. FIGS. 24(c) and (d) are circuit diagrams illustrating circuit configurations of conventional Hartley oscillators. FIG. 24(c) illustrates a configuration that uses an nMOSFET, and FIG. 24(d) illustrates a configuration that uses a pMOSFET. Reference character MN1 denotes an nMOSFET. Reference character MP1 denotes a pMOSFET. Reference characters L1 and L2 denote inductors. Reference character C1 denotes a capacitor. Reference character 11 denotes a current source.

Low-frequency noise (1/f noise) characteristic is an important design consideration in high-frequency analog circuits. FIG. 25(a) illustrates low-frequency noise characteristics of a bipolar transistor and surface-channel nMOSFET and pMOSFET, and FIG. 25(b) illustrates the noise characteristic (phase noise characteristic) of an oscillator. For example, when a transistor with the low-frequency noise characteristic shown in FIG. 25(a) is used for an oscillator, the low-frequency noise component is upconverted inside the oscillator, emerging as phase noise in a side band portion of the desired band, so the noise characteristic of the oscillator as a whole turns out to be as shown in FIG. 25(b). As shown in the figure, the low-frequency component (1/f) of the transistor is upconverted, and emerges as an 1/f³ characteristic (i.e., the S1 portion of FIG. 25(a) corresponds to the S2 portion of FIG. 25(b)). In this way, the larger the 1/f³ phase noise that originates from the low-frequency noise of the transistor emerges as very large phase noise at a frequency closer to the desired wave component. Therefore, in a communication system with a narrow bandwidth, interference to adjacent channels occurs, and therefore, particularly the low frequency noise needs to be reduced. For this reason, the transistors used for oscillators require good low-frequency noise characteristics. However, the low-frequency noise of the commonly-used surface-channel nMOSFET is about 100 times worse than that of the bipolar transistor, and even the surface-channel pMOSFET shows about 10 times worse low-frequency noise than that of the bipolar transistor (see FIG. 25(a)). In view of this, an analog integrated circuit using buried-channel MOSFETs, which have relatively good low-frequency noise characteristics, has been proposed (for example, see Patent References 1 and 2).

[Patent Reference 1] Japanese Patent No. 3282375

[Patent Reference 2] Japanese Unexamined Patent Publication 2002-151599

[Non-patent Reference 1] Jri Lee and Behzad Razavi, “A 40-GHz Frequency Divider in 0.18-μm CMOS Technology”, Symp. VLSI Circuits, 2003, pp. 259-262.

### DISCLOSURE OF THE INVENTION

### Problems the Invention is to Solve

Nevertheless, the level of the low-frequency noise improved with the use of buried-channel MOSFET results in only about ⅓ to ⅕ that of the surface-channel MOSFET, and accordingly the oscillator that employs the buried-channel MOSFET does not yield a good noise characteristic. Such a problem also arises for the cross-coupled differential oscillator and the ring oscillator as well as the Colpitts oscillator and the Hartley oscillator as shown in FIGS. 21 to 24, which use MOSFETs.

The present invention resolves the foregoing conventional problems, and it is an object of the invention to achieve, with buried-channel field effect transistors, low-frequency noise characteristics comparable to the low-frequency noise characteristics of bipolar transistors, and to thus provide a low-cost and low-noise oscillator that is suitable for semiconductor integrated circuits.

### Means to Solve the Problems

In order to accomplish the foregoing object, the invention provides an oscillator comprising: a first power supply wire; a second power supply wire applied with a power supply voltage between the first power supply wire and the second power supply wire, a resonant circuit; a pair of first and second field-effect transistors, the source regions of which are electrically connected to each other and the drain regions of which are electrically connected to the resonant circuit and mutually differentially connected; and a current source connected between the second power supply wire and a portion where the source regions of the first and second field-effect transistors are electrically connected to each other; wherein each of the first and second field-effect transistors is a buried channel transistor comprising a body region of a first conductivity type, formed on a semiconductor substrate, the source region and the drain region of a second conductivity type, formed on the body region, a buried channel layer formed between the source region and the drain region, and a gate electrode formed above the buried channel layer with a gate insulating film interposed therebetween, each of the first and second field-effect transistors being provided with a body terminal electrically connected to the body region; and wherein the oscillator comprises a body potential applying circuit configured to apply a body potential to the body terminal so that a differential voltage between a voltage drop of the current source and a voltage that is between a potential of the second power supply wire and the body potential applied to the body terminal is applied, in a forward direction, to a semiconductor junction between the body region and the source region of each of the first and second field-effect transistors, and so that the body potential is equal to or lower than a diffusion potential difference of the semiconductor junction.

In this configuration, the buried-channel field effect transistor is used for the first and second field-effect transistor, and a body potential is applied from the body potential applying circuit via the body terminal to the body region so that a forward voltage is applied to the semiconductor junction (pn junction) between the body region and the source region. This enables many of carriers (for example, electrons in the case of nMOSFETs, or holes in the case of pMOSFETs), which are the conveyers of electric charge, to be localized in the buried channel layer portion, making it possible to reduce the carriers in the parasitic channel region, which are the main cause of the low-frequency noise. Thereby, the low-frequency noise of the transistors reduces, realizing an oscillator with an improved noise characteristic. Moreover, by controlling the forward voltage applied to the semiconductor junction between the body region and the source region to be a voltage equal to or less than the diffusion potential difference, electric current is prevented from flowing between the body region and the source region, and the stability of the transistor operations can be maintained while unnecessary power consumption is suppressed.

In the present invention, it is possible to employ a configuration wherein: the first conductivity type is n type, the second conductivity type is p type, and the first and second field-effect transistors are p-channel field effect transistors; the first power supply wire is a lower potential-side power supply wire, and the second power supply wire is a higher potential-side power supply wire; and the body potential applying circuit is a wire that connects the body terminal to the lower potential-side power supply wire. Connecting the body terminal to an existing power supply wire in this way eliminates the need for the external power supply for applying a potential to the body terminal, and achieves size reduction of the circuit scale.

It is also possible to employ a configuration wherein: the first conductivity type is p type, the second conductivity type is n type, and the first and second field-effect transistors are n-channel field effect transistors; the first power supply wire is a higher potential-side power supply wire, and the second power supply wire is a lower potential-side power supply wire; and the body potential applying circuit is a wire that connects the body terminal to the higher potential-side power supply wire. Connecting the body terminal to an existing power supply wire in this way eliminates the need for the external power supply for applying a potential to the body terminal, and can achieve size reduction of the circuit scale.

In this case, the oscillator may further comprise a pair of first and second p-channel field effect transistors differentially connected to each other, each of source regions of the first and second p-channel field effect transistors being electrically connected to the higher potential-side power supply wire and each of drain regions of the first and second p-channel field effect transistors being electrically connected to the resonant circuit; wherein each of the first and second p-channel field effect transistor may be a buried channel transistor comprising an n-type body region formed on the semiconductor substrate, the source region and the drain region of p-type formed on the body region, a buried channel layer formed between the source region and the drain region, and a gate electrode formed above the buried channel layer with a gate insulating film interposed therebetween, the buried channel transistor being provided with a body terminal electrically connected to the body region, and the body terminal may be connected to the lower potential-side power supply wire; and wherein the power supply voltage may be applied in a forward direction to the semiconductor junction between the body region and the source region of each of the first and second p-channel field effect transistors, and may be equal to or lower than the diffusion potential difference of the semiconductor junction.

In this way, the buried-channel field effect transistor is used also for the first and second p-channel field effect transistors further provided, and a forward voltage is applied to the semiconductor junction (pn junction) between the body region and the source region in each of them. This enables many of carriers (holes), which are the conveyers of electric charge, to be localized in the buried channel layer portion, making it possible to reduce the carriers in the parasitic channel region, which are the main cause of the low-frequency noise. Thereby, the low-frequency noise of the transistors reduces, realizing an oscillator with an improved noise characteristic. Moreover, by controlling the forward voltage applied to the semiconductor junction between the body region and the source region to be a voltage equal to or less than the diffusion potential difference, electric current is prevented from flowing between the body region and the source region, and the stability of the transistor operations can be maintained while unnecessary power consumption is suppressed. In addition, connecting the body terminals of the p-channel field effect transistors also to an existing power supply wire eliminates the need for the external power supply for applying a potential to the body terminals, and can achieve size reduction of the circuit scale.

It is possible to employ a configuration wherein: the first conductivity type is n-type, the second conductivity type is p-type, and the first and second field-effect transistors are p-channel field effect transistors; the first power supply wire is a lower potential-side power supply wire, and the second power supply wire is a higher potential-side power supply wire; and the body potential applying circuit is a circuit connected between the higher potential-side power supply wire and the lower potential-side power supply wire, and configured to apply, as the body potential, a potential equivalent to a divided voltage of the power supply voltage to the body terminal. Using a voltage divider circuit for dividing the power supply voltage as the body potential applying circuit in this way allows the potential applied to the body terminal to be set arbitrarily, and serves to easily control the forward voltage applied to the semiconductor junction between the body region and the source region to be a voltage equal to or lower than the diffusion potential difference.

It is also possible to employ a configuration wherein: the first conductivity type is p type, the second conductivity type is n type, and the first and second field-effect transistors are n-channel field effect transistors; the first power supply wire is a higher potential-side power supply wire, and the second power supply wire is a lower potential-side power supply wire; and the body potential applying circuit is a circuit configured to apply, as the body potential, a potential equivalent to a divided voltage of the power supply voltage to the body terminal. Using a voltage divider circuit for dividing the power supply voltage as the body potential applying circuit in this way allows the potential applied to the body terminal to be set arbitrarily, and serves to easily control the forward voltage applied to the semiconductor junction between the body region and the source region to be a voltage equal to or lower than the diffusion potential difference.

In this case, the oscillator may further comprise: a pair of first and second p-channel field effect transistors differentially connected to each other, each of source regions of said first and second p-channel field effect transistors being electrically connected to said higher potential-side power supply wire and each of drain regions of said first and second p-channel field effect transistors being electrically connected to said resonant circuit; wherein each of said first and second p-channel field effect transistors may be a buried channel transistor comprising an n-type body region formed on said semiconductor substrate, said source region and said drain region of p-type formed on said body region, a buried channel layer formed between said source region and said drain region, and a gate electrode formed above said buried channel layer with a gate insulating film interposed therebetween, each of said first and second p-channel field effect transistors being provided with a body terminal electrically connected to said body region; and wherein said oscillator further may comprise a voltage divider circuit connected between said higher potential-side power supply wire and said lower potential-side power supply wire and configured to apply a potential equivalent to a divided voltage of the power supply voltage to said body terminal of each of said first and second p-channel field effect transistors; and wherein a differential voltage between a potential of said higher potential-side power supply wire and a potential applied by the voltage divider circuit to said body terminal of each of said first and second p-channel field effect transistors may be applied, in a forward direction, to the semiconductor junction between said body region and said source region of each of said first and second field-effect transistors, and the differential voltage may be equal to or lower than a diffusion potential difference of said semiconductor junction.

In this way, the buried-channel field effect transistor is used also for the first and second p-channel field effect transistors further provided, and a forward voltage is applied to the semiconductor junction (pn junction) between the body region and the source region in each of them. This enables many of carriers (holes), which are the conveyers of electric charge, to be localized in the buried channel layer portion, making it possible to reduce the carriers in the parasitic channel region, which are the main cause of the low-frequency noise. Thereby, the low-frequency noise of the transistors reduces, realizing an oscillator with an improved noise characteristic. Moreover, by controlling the forward voltage applied to the semiconductor junction between the body region and the source region to be a voltage equal to or less than the diffusion potential difference, electric current is prevented from flowing between the body region and the source region, and the stability of the transistor operations can be maintained while unnecessary power consumption is suppressed. Furthermore, using a voltage divider circuit for dividing the power supply voltage allows the potential applied to the body terminals of the p-channel field effect transistors to be set arbitrarily, and serves to easily control the forward voltage applied to the semiconductor junction between the body region and the source region to be a voltage equal to or lower than the diffusion potential difference. In addition, in the case of this configuration, from the point of view of reducing the circuit scale, it is not preferable to separately configure the body potential applying circuit comprising the voltage divider circuit for applying a potential to the body terminals of the n-channel field effect transistors and the voltage divider circuit for applying a potential to the body terminals of the p-channel field effect transistors, but it is preferable to configure them as a single voltage divider circuit that can apply both the potential applied to the body terminals of the n-channel field effect transistors and the potential applied to the body terminals of the p-channel field effect transistors.

It is possible to employ a configuration wherein the semiconductor substrate is composed mainly of silicon, and the buried channel layer of the p-channel field effect transistor is formed of a SiGe layer or a SiGeC layer.

It is possible to employ a configuration wherein the semiconductor substrate is composed mainly of silicon, and the buried channel layer of the n-channel field effect transistor is formed of a SiC layer or a SiGeC layer.

It is possible to employ a configuration wherein the semiconductor substrate is composed mainly of silicon; the buried channel layer of the p-channel field effect transistor is formed of a SiGe layer or a SiGeC layer; and the buried channel layer of the n-channel field effect transistor is formed of a SiC layer or a SiGeC layer.

It is preferable that a distance from the gate insulating film to the buried channel layer be longer than 0 nm and shorter than 5 nm, from the point of view of improving the electrical characteristics of the field-effect transistor.

It is more preferable that a distance from the gate insulating film to the buried channel layer be longer than 0.5 nm and shorter than 3 nm, from the point of view of improving the electrical characteristics of the field-effect transistor.

The configuration of another oscillator according to the present invention may be an oscillator comprising a field-effect transistor as an amplifier element, wherein the field-effect transistor is a buried channel transistor comprising a body region formed on a semiconductor substrate, a source region and a drain region formed on the body region and having a different conductivity type from the body region, a buried channel layer formed between the source region and drain region, a gate electrode formed above the buried channel layer with a gate insulating film interposed therebetween, and wherein the buried channel transistor is provided with a body terminal electrically connected to the body region.

In this configuration, the buried-channel field effect transistor is used, and a potential is applied from the body terminal to the body region so that a forward voltage is applied to the semiconductor junction (pn junction) between the body region and the source region. This enables many of carriers (for example, electrons in the case of nMOSFETs, or holes in the case of pMOSFETs), which are the conveyers of electric charge, to be localized in the buried channel layer portion, making it possible to reduce the carriers in the parasitic channel region, which are the main cause of the low-frequency noise. This reduces the low-frequency noise of the transistor, realizing an oscillator with an improved noise characteristic.

In the above-described other oscillator, a forward voltage that is equal to or lower than the diffusion potential difference of the semiconductor junction may be applied to the semiconductor junction between the body region and the source region by applying a predetermined potential to the body terminal of the field-effect transistor from outside. Controlling the forward voltage applied to the semiconductor junction between the body region and the source region to be a voltage equal to or less than the diffusion potential difference prevents electric current from flowing between the body region and the source region, whereby the stability of the transistor operations can be maintained while unnecessary power consumption is suppressed.

The above-described other oscillator may further comprise a higher potential-side power supply wire and a lower potential-side power supply wire applied with a power supply voltage between the lower potential-side power supply wire and the higher potential-side power supply wire, and wherein the field-effect transistor may be an n-channel field effect transistor, and the body terminal may be connected to the higher potential-side power supply wire. In this case, no external power supply is necessary for applying a potential to the body terminal, and connecting the body terminal to an existing power supply wire achieves a size reduction of the circuit scale.

The above-described other oscillator may further comprise a higher potential-side power supply wire and a lower potential-side power supply wire applied with a power supply voltage between the lower potential-side power supply wire and the higher potential-side power supply wire, and wherein the field-effect transistor may be an p-channel field effect transistor, and the body terminal may be connected to the lower potential-side power supply wire. In this case, no external power supply is necessary for applying a potential to the body terminal, and connecting the body terminal to an existing power supply wire achieves a size reduction of the circuit scale.

The above-described other oscillator may further comprise a higher potential-side power supply wire, a lower potential-side power supply wire applied with a power supply voltage between the lower potential-side power supply wire and the higher potential-side power supply wire, and a plurality of the field effect transistors which include one n-channel field effect transistor and one p-channel field effect transistor, and wherein the body terminal of the n-channel field effect transistor may be connected to the higher potential-side power supply wire, and wherein the body terminal of the n-channel field effect transistor may be connected to the lower potential-side power supply wire. In this case, no external power supply is necessary for applying a potential to the body terminal, and connecting the body terminal to an existing power supply wire achieves a size reduction of the circuit scale.

In the above-described other oscillator, it is preferable that when the body terminal is connected to a power supply wire, a forward voltage that is equal to or lower than a diffusion potential difference of the semiconductor junction be applied to the semiconductor junction between the body region and the source region of the field-effect transistor. Thereby, electric current is prevented from flowing between the body region and the source region, and the stability of the transistor operations can be maintained while unnecessary power consumption is suppressed.

The above-described other oscillator may further comprise a higher potential-side power supply wire, a lower potential-side power supply wire applied with a power supply voltage between the lower potential-side power supply wire and the higher potential-side power supply wire, and a voltage divider circuit configured to apply a potential equivalent to a divided voltage of the power supply voltage to the body terminal. In this case, the potential applied to the body terminal may be arbitrarily set by the voltage divider circuit.

The above-described other oscillator may further comprise a higher potential-side power supply wire, a lower potential-side power supply wire applied with a power supply voltage between the lower potential-side power supply wire and the higher potential-side power supply wire, and a plurality of the field effect transistors which include an n-channel field effect transistor and a p-channel field effect transistor, and wherein oscillator may further comprise a voltage divider circuit which is connected between the higher potential-side power supply wire and the lower potential-side power supply wire and configured to apply a potential equivalent to a first voltage that is a divided voltage of the power supply voltage to the body terminal of the p-channel field effect transistor and to apply a potential equivalent to a second voltage that is a divided voltage of the power supply voltage to the body terminal of the n-channel field effect transistor. In this case, the potential applied to the body terminal may be arbitrarily set by the voltage divider circuit.

When the voltage divider circuit is provided in the above-described other oscillator, it is preferable that in the field-effect transistor, by applying the potential from the voltage divider circuit to the body terminal, a forward voltage that is equal to or lower than the diffusion potential difference of the semiconductor junction is applied to the semiconductor junction between the body region and the source region. Thereby, electric current is prevented from flowing between the body region and the source region, and the stability of the transistor operations can be maintained while unnecessary power consumption is suppressed.

In the above-described other oscillator, it is also possible to employ a configuration wherein the semiconductor substrate is composed mainly of silicon, and the field-effect transistor is an n-channel field effect transistor in which the buried channel layer is formed of a SiC layer or a SiGeC layer. Alternatively, it is also possible to employ a configuration wherein the semiconductor substrate is composed mainly of silicon, and the field-effect transistor is a p-channel field effect transistor in which the buried channel layer is formed of a SiGe layer or SiGeC layer. Alternatively, when both a p-channel field effect transistor and an n-channel field effect transistor are used, it is also possible to employ a configuration wherein the semiconductor substrate is composed mainly of silicon, and the p-channel field effect transistor has a buried channel layer formed of a SiGe layer or a SiGeC layer, and the n-channel field effect transistor has the buried channel layer formed of a SiC layer or a SiGeC layer.

The foregoing and other objects, features, and advantages of the present invention will become more readily apparent from the following detailed description of preferred embodiments of the invention, with reference to the accompanying drawings.

### ADVANTAGES OF THE INVENTION

The present invention has the configurations as described above, and makes available the advantageous effect of achieving, with buried-channel field effect transistors, low-frequency noise characteristics comparable to the low-frequency noise characteristics of bipolar transistors, and thus providing a low-cost and low-noise oscillator that is suitable for semiconductor integrated circuits.

### BRIEF DESCRIPTION OF THE DRAWINGS

FIGS. 1(a) and (b) are cross-sectional structural views illustrating transistors (surface-channel Si-pMOSFET and SiGe-pMOSFET) used for an experiment for explaining a transistor used in an embodiment of the present invention, and FIGS. 1(c) and (d) are energy band diagrams of the respective transistors.

FIG. 2 is a set of low-frequency noise characteristic graphs for the surface-channel Si-pMOSFET and the SiGe-pMOSFET shown in FIG. 1.

FIG. 3(a) is a low-frequency noise characteristic graph, measured by varying the body-source voltage of the surface-channel Si-pMOSFET, and FIG. 3(b) is a low-frequency noise characteristic graph, measured by varying the body-source voltage of the SiGe-pMOSFET.

FIG. 4(a) is a graph illustrating the relationship between body-source voltage versus drain current noise of the SiGe-pMOSFET, and FIG. 4(b) is a graph illustrating the relationship between body-source voltage versus equivalent input noise of the SiGe-pMOSFET.

FIG. 5(a) is a graph illustrating the relationship between drain current noise (measured value) and carrier density (simulated value) versus body-source voltage of a surface-channel Si-pMOSFET, and FIG. 5(b) is a graph illustrating the relationship between drain current noise (measured value) and carrier density (simulated value) versus body-source voltage of a SiGe-pMOSFET.

FIGS. 6(a) to (c) are cross-sectional structural views of other examples of the buried channel transistor used in an embodiment of the present invention, and FIG. 6(d) to (I) are energy band diagrams of the respective transistors.

FIGS. 7(a) and (b) are cross-sectional structural views of other examples of the buried channel transistor used in an embodiment of the present invention, and FIGS. 7(c) and (d) are energy band diagrams of the respective transistors.

FIG. 8(a) to (c) are circuit diagrams each illustrating one example of the oscillator according to a first embodiment of the present invention, and FIGS. 8(d) to (f) are circuit diagrams illustrating the circuits generally.

FIG. 9(a) is a circuit diagram of an LC oscillator used for a simulation of one example of the oscillator according to the first embodiment of the present invention, FIG. 9(b) is a graph of the simulation results, illustrating the relationship between oscillation frequency versus source-drain forward voltage, and FIG. 9(c) a graph of the simulation results, illustrating the relationship between CN (signal to noise ratio) versus source-drain forward voltage.

FIG. 10(a) to (c) are circuit diagrams each illustrating one example of the oscillator according to a second embodiment of the present invention, and FIGS. 10(d) to (f) are circuit diagrams illustrating the circuits generally.

FIG. 11(a) to (c) are circuit diagrams each illustrating one example of the oscillator according to a third embodiment of the present invention, and FIGS. 11(d) to (f) are circuit diagrams illustrating the circuits generally.

A diagram illustrating one example of the oscillator according to a third embodiment of the present invention.

FIGS. 12(a) to (c) are circuit diagrams illustrating other examples of the oscillator according to the first embodiment of the present invention.

FIGS. 13(a) to (c) are circuit diagrams illustrating other examples of the oscillator according to the second embodiment of the present invention.

FIGS. 14(a) to (c) are circuit diagrams illustrating other examples of the oscillator according to the third embodiment of the present invention.

FIGS. 15(a) to (c) are circuit diagrams illustrating other examples of the oscillator according to the first embodiment of the present invention.

FIGS. 16(a) to (c) are circuit diagrams illustrating other examples of the oscillator according to the second embodiment of the present invention.

FIGS. 17(a) to (c) are circuit diagrams illustrating other examples of the oscillator according to the third embodiment of the present invention.

FIGS. 18(a) to (d) are circuit diagrams illustrating other examples of the oscillator according to the first embodiment of the present invention.

FIGS. 19(a) to (d) are circuit diagrams illustrating other examples of the oscillator according to the second embodiment of the present invention.

FIGS. 20(a) to (d) are circuit diagrams illustrating other examples of the oscillator according to the third embodiment of the present invention.

FIGS. 21(a) to (c) are circuit diagrams each illustrating one example of a conventional oscillator, and FIGS. 21(d) to (f) are circuit diagrams illustrating the respective circuits thereof generally.

FIGS. 22(a) to (c) are circuit diagrams illustrating other examples of the conventional oscillator.

FIGS. 23(a) to (c) are circuit diagrams illustrating other examples of the conventional oscillator.

FIGS. 24(a) to (d) are circuit diagrams illustrating other examples of the conventional oscillator.

FIG. 25(a) is a low-frequency noise characteristic graph of a transistor, and FIG. 25(b) is a noise characteristic graph of an oscillator.

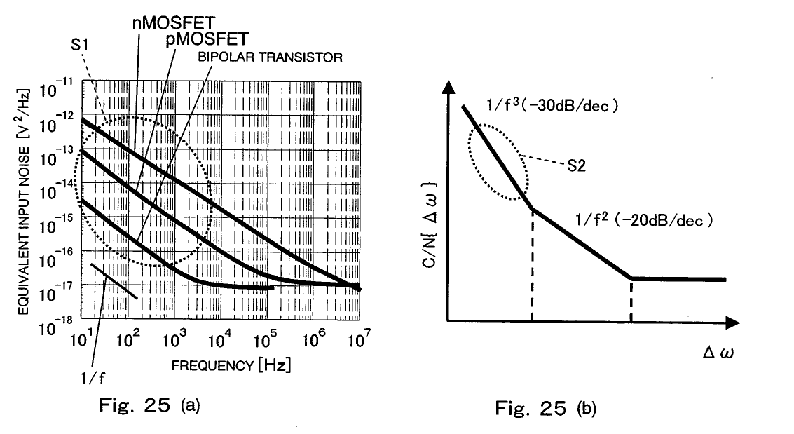

FIG. 26(a) is a graph showing measurement results of transconductance (gm) in the case that the film thickness of the Si cap layer of the SiGe-pMOSFET is controlled to be 1 nm, and FIG. 26(b) is a graph showing measurement results of transconductance (gm) in the case that the film thickness of the Si cap layer of the SiGe-pMOSFET is controlled to be 6 nm.

FIG. 27(a) is a graph showing the simulation results of carrier density of a region immediately below the gate insulating film of the SiGe-pMOSFET in the case that the film thickness of the Si cap layer is controlled to be 1 nm, and FIG. 27(b) is a graph showing the simulation results of carrier density of the region immediately below the gate insulating film of the SiGe-pMOSFET in the case that the film thickness of the Si cap layer is controlled to be 6 nm.

FIG. 28(a) is a graph showing the simulation results of drain current Id versus gate-source voltage Vg of the SiGe-pMOSFET, and FIG. 28(b) is a graph showing the simulation results of transconductance gm versus gate-source voltage Vg of the SiGe-pMOSFET.

FIG. 29(a) is a circuit diagram of an LC oscillator used for a simulation conducted regarding phase noise, using an ideal current source for a current source of an oscillator, and FIG. 29(b) is a characteristic graph of phase noise showing the simulation results.

FIG. 30(a) is a circuit diagram of an LC oscillator used for a simulation conducted regarding phase noise, using various transistors for a current source of an oscillator, and FIG. 30(b) is a characteristic graph of phase noise, which shows part of the simulation results.

FIG. 31 is a table that summarizes the results of simulations conducted regarding phase noise, using various transistors for a current source of an oscillator.

### DESCRIPTION OF THE REFERENCE NUMERALS

10, 11 surface-channel nMOSFET
12, 13 buried-channel nMOSFET
20, 21 surface-channel pMOSFET
22, 23 buried-channel pMOSFET
30, 31, 32 inductor
33, 34, 35 capacitor
36 current source
37 LC resonant circuit
38, 39, 40, 41, 42, 43 resistor
51 silicon substrate
52 n-type well
53 p-type well
54 source
55 drain
56 element-isolating insulator region
57 gate insulating film
58 gate electrode
59 conduction band
60 valence band
61 hole
62 electron
63 parasitic channel
65 SiGe channel layer
66 Si cap layer
67 SiC channel layer
68 SiGeC channel layer
69 n-type counter doping layer
70 p-type counter doping layer

### BEST MODE FOR CARRYING OUT THE INVENTION

Hereinbelow, preferred embodiments of the present invention will be described with reference to the drawings.

### (Concept of the Invention)

In the oscillator according to the embodiments of the present invention, buried-channel MOSFETs are used for the amplifier circuit, and a potential is applied to the body region so that a forward bias is applied to the semiconductor junction between the body and the source (between the body region and the source). Applying a forward voltage between the body and the source can significantly improve the low-frequency noise characteristics of the buried-channel MOSFETs. The present invention is based on this finding, and we have confirmed this operation through the experiments and simulations described below.

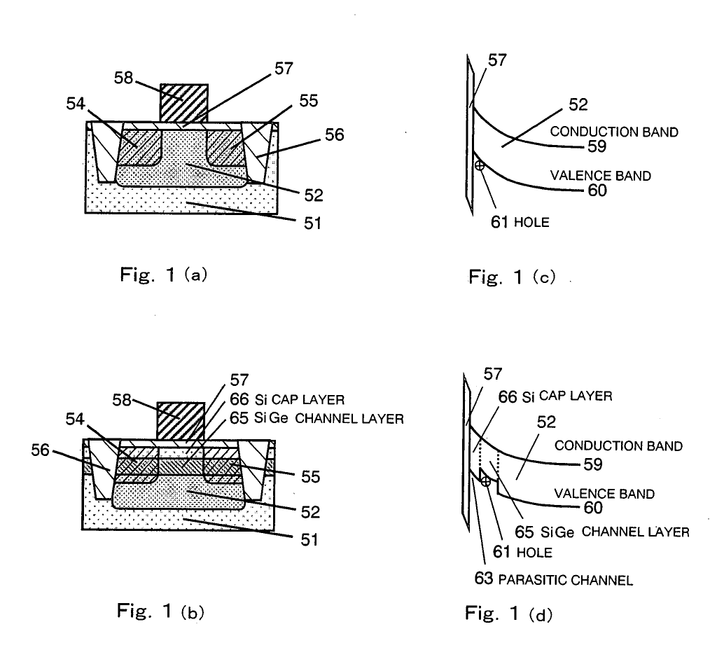

FIG. 1(a) is a cross-sectional structural view of a conventional surface-channel pMOSFET (hereinafter referred to as a “surface-channel Si-pMOSFET”), which was used in an experiment and a simulation, and FIG. 1(c) is an energy band diagram of the surface-channel Si-pMOSFET. This surface-channel Si-pMOSFET comprises an n-type well 52 formed on a silicon substrate 51, a p-type source 54 and a p-type drain 55 formed on the n-type well 52, and a gate electrode 58 formed above a region between the source 54 and the drain 55 with a gate insulating film 57 interposed therebetween, and it has a surface-channel structure in which a hole 61 travels through the interface between the gate insulating film 57 and the Si layer. Reference numeral 56 denotes an element-isolating insulator region.

FIG. 1(b) is a cross-sectional structural view of a buried-channel pMOSFET having a SiGe layer as the channel layer (hereinafter referred to as a “SiGe-pMOSFET”), which was used in the experiment and simulation, and FIG. 1(d) is an energy band diagram of the SiGe-pMOSFET. This SiGe-pMOSFET comprises an n-type well 52 formed on a silicon substrate 51, a p-type source 54 and a p-type drain 55 formed on the n-type well 52, a SiGe (Si₁₋ₓGeₓ) channel layer 65 formed between the source 54 and the drain 55, a Si cap layer 66 formed on the SiGe channel layer 65, and a gate electrode 58 formed above the Si cap layer 66 with a gate insulating film 57 interposed therebetween. In the following experiment and simulation, a Si_{0.7}Ge_{0.3} layer is used as the SiGe channel layer 65.

In the case of the SiGe-pMOSFET shown in FIG. 1(b), a buried structure in which a hole 61 travels through the interface between the Si cap layer 66 and the SiGe channel layer 65 can be achieved since a band offset occurs in a valence band 60 at the semiconductor junction between the Si layer and the SiGe layer. The thicknesses of the SiGe channel layer 65 and the Si cap layer 66 are 15 nm and 5 nm, respectively.

A fabrication method of this SiGe-pMOSFET will be described briefly. Arsenic (As) is ion implanted into the Si substrate 51 to form the n-type well 52 having an impurity concentration of about 2×10¹⁸ cm⁻³. Thereafter, using UHV-CVD equipment, crystal growth is effected for the SiGe channel layer 65 and the Si cap layer 66. The growth temperature is 530° C., and disilane and germane are used for the source gas. Before the crystal growth for the SiGe channel layer 65, a Si buffer layer with a thickness of about 5 nm may be formed by crystal growth. By thermally oxidizing the Si cap layer 66 after the crystal growth, a 6-nm thick SiO₂ gate insulating film 57 is formed. Next, polysilicon is deposited to a thickness of about 200 nm, and a gate electrode 58 is formed using resist patterning by lithography and dry etching. Thereafter, boron (B) is ion implanted to form the source 54 and the drain 55. Lastly, A1 wires (not shown) are formed, to thus complete the device.

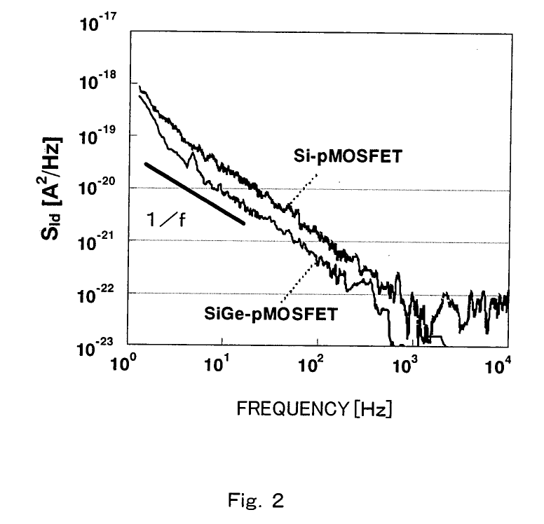

FIG. 2 illustrates the characteristics of drain current noise (S_{Id}) of the surface-channel Si-pMOSFET and the SiGe-pMOSFET. The device dimensions are; the gate length is 1 μm and the gate width is 10 μm. The voltage conditions during the measurement are; Vg−Vt is −0.3V, and Vd is −0.5V, where Vg is gate-source voltage, Vt is threshold voltage, and Vd is drain-source voltage. It is clear from FIG. 2 that the drain current noise of the SiGe-pMOSFET can be reduced to about ¼ of that of the surface-channel Si-pMOSFET. This phenomenon relates to the interface state density in which carriers move. The interface state density of the SiO₂ gate oxide film and the Si layer is reported to show a large value, about 10¹² cm⁻² in many reports, which is higher than the interface state density of heterointerface, although the values vary depending on the formation process of the gate oxide film. Therefore, a buried-channel transistor such as the SiGe-pMOSFET achieves an improvement in low-frequency noise characteristic because the buried-channel transistor such as the SiGe-pMOSFET is not easily affected by interface between the gate oxide film and the Si layer. The low-frequency noise characteristic thereof is not as good a value as that of the bipolar transistor. In view of this, we have made measurements and evaluations detailed below, and as a result, we have found that the charge layer (parasitic channel 63) that parasitically emerges in the gate-oxide-film/Si interface, shown in the energy band diagram of FIG. 1(d), has an influence on the noise characteristics.

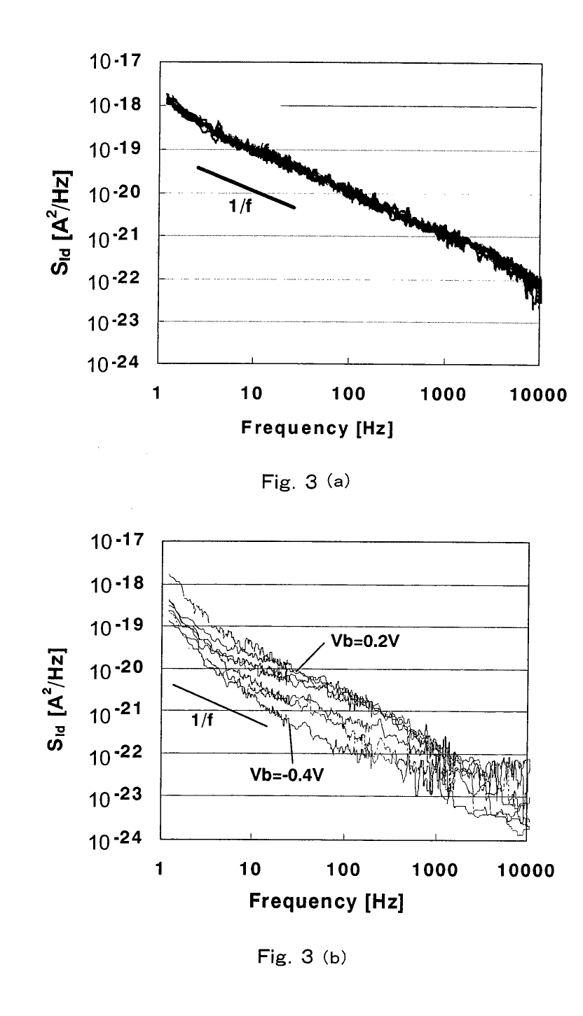

FIG. 3(a) shows the frequency characteristic of the drain current noise (S_{Id}) of the surface-channel Si-pMOSFET, measured by varying the applied voltage Vb (body-source voltage) between the body region (n-type well 52) and the source region, and FIG. 3(b) shows the frequency characteristic of the drain current noise (S_{Id}) of the SiGe-pMOSFET, measured by varying the applied voltage Vb (body-source voltage) between the body region (n-type well 52) and the source region. In both cases of FIG. 3(a) and FIG. 3(b), the device dimensions are the same as that in the case of FIG. 2; and Vg−Vt is −0.3 V and Vd is −0.5 V. In both cases, the body-source voltage Vb is changed in a stepwise manner in decrements of 0.1 V from +0.2 V to −0.4 V by varying the potential applied to the body region, and each of the graphs show the measurement results at which each voltage Vb (+0.2 V, +0.1V, +0.0V, −0.1V, −0.2V, −0.3V, −0.4V) is applied. Generally, as the drain current value increases, the drain current noise value correspondingly becomes large. For this reason, the gate voltage is controlled so that the drain current value stays approximately constant even when the body-source voltage Vb is varied. As clearly seen from FIG. 3(a), the low-frequency noise characteristic in the surface-channel Si-pMOSFET is little dependent on the body-source voltage Vb and almost constant. On the other hand, in the case of the buried-channel SiGe-pMOSFET shown in FIG. 3(b), as the forward voltage applied between the body and the source increases, the low-frequency noise reduces and the noise characteristic improves.

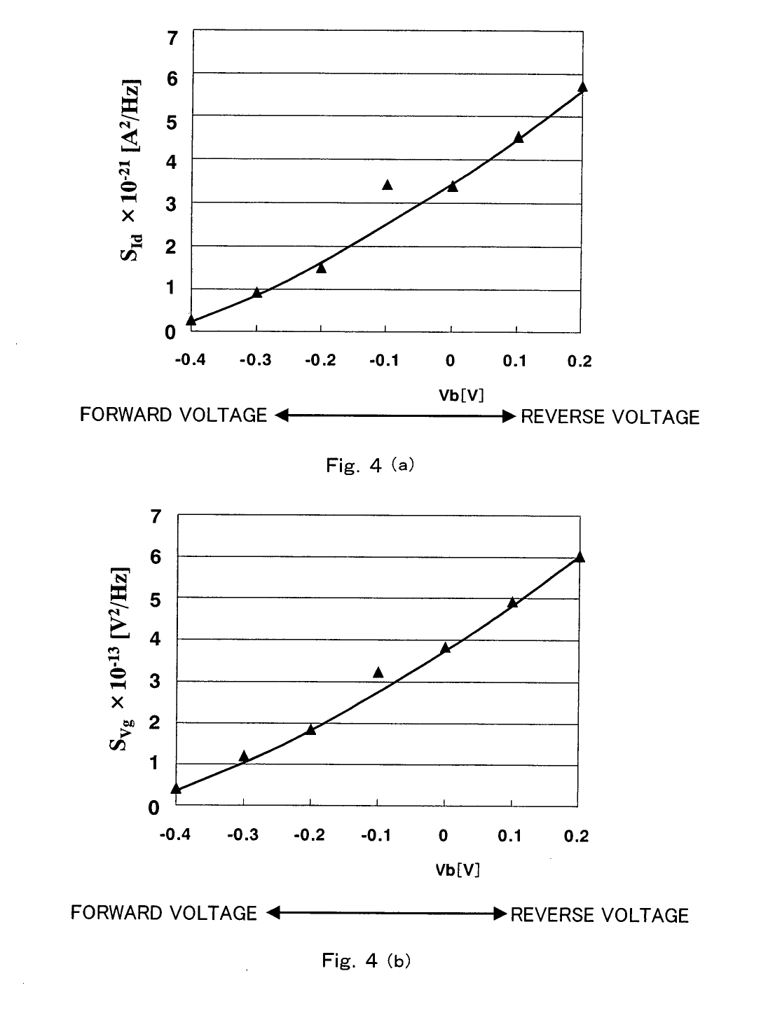

FIG. 4 includes graphs in which the noise characteristic values at 50 Hz of the SiGe-pMOSFET are plotted versus body-source voltage Vb. FIG. 4(a) shows drain current noise (S_{Id}) and FIG. 4(b) shows equivalent input noise (S_{Vg}). The equivalent input noise means a value of drain current noise converted to a gate input, which is obtained by dividing a drain current noise value by the square of transconductance (gm). It is clear from FIGS. 4(a) and 4(b) that, as the forward voltage applied between the body and the source increases, the noise characteristic of the SiGe-pMOSFET improves. In the case that the body-source voltage Vb is a forward voltage of −0.4 V, the low-frequency noise characteristic improves by about one order of magnitude in comparison with the case that no voltage is applied. Accordingly, the low-frequency noise characteristic of the buried-channel SiGe-pMOSFET reduces to 1/40 or less of that of the surface-channel Si-pMOSFET, by applying a forward voltage between the body and the source in addition to the advantageous effect achieved by the buried channel.

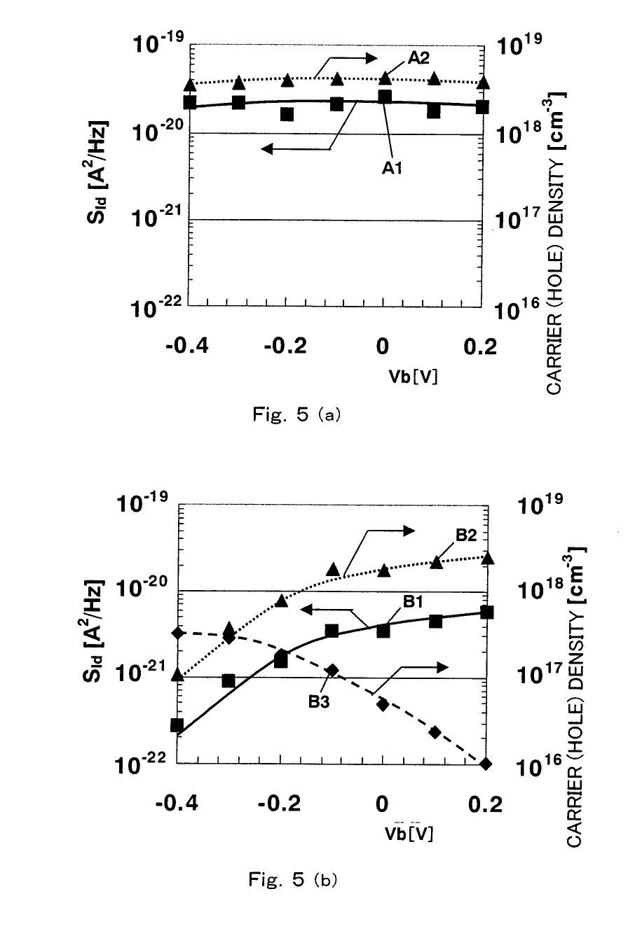

In order to further make clear the advantageous effect of applying a forward voltage between the body and the source, a device simulation was carried out using a Medici device simulator. FIG. 5(a) is a graph in which measured values (A1) of drain current noise S_{Id} at 50 Hz and carrier densities (A2), obtained by the simulation, of the SiO₂ gate insulating film/Si interface of the surface-channel Si-pMOSFET are plotted verses body-source voltage Vb. FIG. 5(b) is a graph in which, with the SiGe-pMOSFET, measured values (B1) of drain current noise S_{Id} at 50 Hz, carrier densities (B2), obtained by the simulation, of the SiO₂ gate insulating film/Si (Si cap layer) interface, and carrier densities (B3), also obtained by the simulation, of the SiGe channel layer in the vicinity of its interface with the Si cap layer are plotted versus body-source voltage Vb. As clearly seen from FIG. 5, there is a strong correlation between the drain current noise values and the numbers of the carriers that are generated in the SiO₂ gate insulating film/Si interface (parasitic channel). In the SiGe-pMOSFET, the greater the forward voltage applied between the body and the source is, the less the number of carriers generated in the parasitic channel and the more the number of carriers in the SiGe channel layer will be. This means that, consequently, only the low-frequency noise characteristic can be dramatically improved without lowering the drain current value.

By the foregoing experiment and simulation, the following were found.

In the buried-channel field effect transistor,

(1) the gate oxide film interface is a dominant factor of low-frequency noise, and the parasitic channel produced in the gate insulating film/Si interface mainly generates the low-frequency noise;

(2) by applying a voltage between the body and the source, the proportions of the carriers generated in the parasitic channel and in the buried channel can be controlled; and

(3) applying a forward voltage between the body and the source makes it possible to reduce the number of carriers generated in the parasitic channel and to increase the number of carriers generated in the buried channel, thus improving the characteristics of the low-frequency noise.

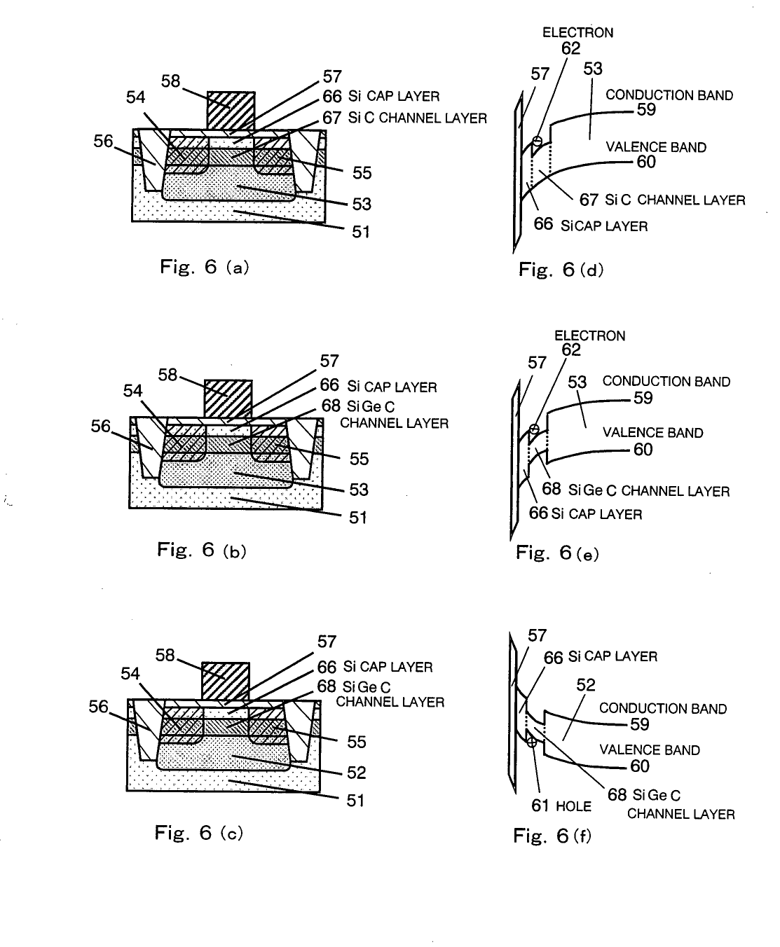

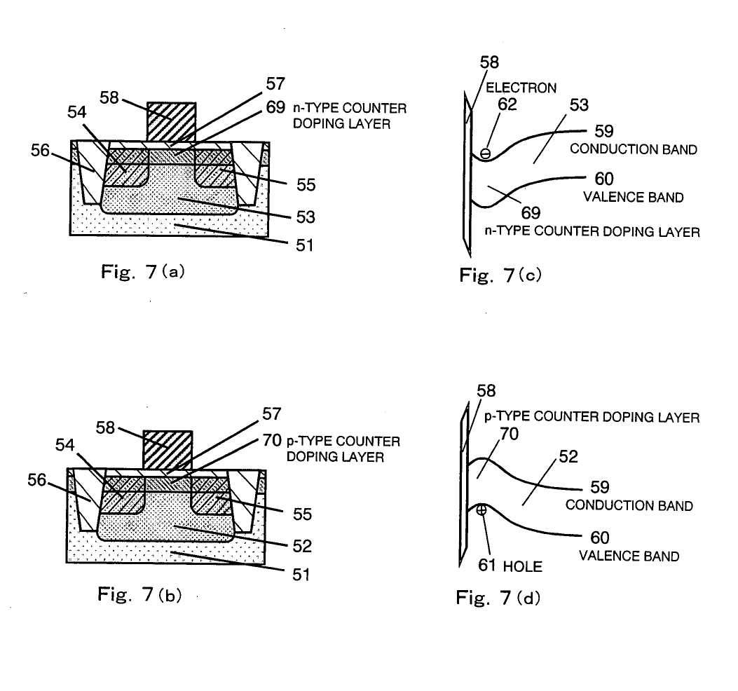

Although the experimental results for a buried channel transistor in which a SiGe layer is the channel layer are shown here, the same advantageous effects can be obtained by applying a forward voltage between the body and the source in a buried-channel field effect transistor that has a similar channel structure. Examples of the buried-channel field effect transistors that can achieve the same advantageous effects are shown in FIGS. 6 and 7.

FIG. 6(a) is a cross-sectional structural view of a buried-channel nMOSFET in which a SiC layer is the channel layer, and FIG. 6(d) is an energy band diagram thereof. In this buried-channel nMOSFET, a p-type well 53 is formed instead of the n-type well 52 of the SiGe-pMOSFET shown in FIG. 1(b), the source 54 and the drain 55 are formed of n-type regions instead of the p-type regions, and a SiC (Si₁₋ₓCₓ) channel layer 67 is formed instead of the SiGe channel layer 65. It is known that a band offset occurs in the conduction band 59 in the semiconductor junction between cubic SiC and Si, and as illustrated in the figure, a buried channel for an electron 62 can be realized at the interface between the Si cap layer 66 and the SiC channel layer 67. The fabrication method for this is similar to the fabrication method for the SiGe-pMOSFET, and major differences are that the p-type well 53 is formed by ion implantation and that disilane and methylsilane are used for the source gas for the crystal growth for the SiC channel layer 67.

FIG. 6(b) is a cross-sectional structural view of a buried-channel nMOSFET in which a SiGeC layer is the channel layer, and FIG. 6(e) is an energy band diagram thereof. In this buried-channel nMOSFET, a SiGeC (Si_{1-x-y}GeₓC_{y}) channel layer 68 is formed instead of the SiC channel layer 67 of the nMOSFET shown in FIG. 6(a). FIG. 6(c) is a cross-sectional structural view of a buried-channel pMOSFET in which a SiGeC (Si_{1-x-y}GeₓC_{y}) layer is the channel layer, and FIG. 6(f) an energy band diagram thereof. In this buried-channel pMOSFET, an n-type well 52 is formed instead of the p-type well 53 of the nMOSFET shown in FIG. 6(b), and the source 54 and the drain 55 are formed of p-type regions instead of the n-type regions. It is known that a band offset occurs in the conduction band and the valence band in the semiconductor junction between SiGeC and Si, and a buried channel can be realized for both electrons and holes. The fabrication methods for these are similar to the fabrication method for the SiGe-pMOSFET, and major differences are that disilane, germane, and methylsilane are used for the source gases for growing crystals for the SiGeC channel layer 68. In the case of FIG. 6(b), another difference is that the p-type well 53 is formed by ion implantation.

In the cases of FIG. 6(a) and FIG. 6(b), since they are nMOSFETs, the source 54 and the drain 55 of n-type regions are formed by ion implantation.

FIG. 7(a) is a cross-sectional structural view of a buried-channel nMOSFET using an n-type counter doping layer (n-type Si layer) 69, and FIG. 7(c) is an energy band diagram thereof. In this buried-channel nMOSFET, a p-type well 53 is formed instead of the n-type well 52 of the SiGe-pMOSFET shown in FIG. 1(b), and the source 54 and the drain 55 are formed of n-type regions instead of the p-type regions, and an n-type counter doping layer 69 is formed instead of the SiGe channel layer 65. In addition, no Si cap layer 66 is provided, and the n-type counter doping layer 69 is formed immediately below and in contact with the gate insulating film 57. A bend in the energy band occurs because of the n-type counter doping layer 69, forming a buried channel for electrons. FIG. 7(b) is a cross-sectional structural view of a buried-channel pMOSFET using a p-type counter doping layer (p-type Si layer) 70, and FIG. 7(d) is an energy band diagram thereof. In this buried-channel pMOSFET, a p-type counter doping layer 70 is formed instead of the SiGe channel layer 65 of the SiGe-pMOSFET shown in FIG. 1(b). In addition, no Si cap layer 66 is provided, and the p-type counter doping layer 70 is formed immediately below and in contact with the gate insulating film 57. A bend in the energy band is produced by the p-type counter doping layer 70, and a buried channel for holes is formed. An ion implantation method may be used to form the counter doping layers 69 and 70.

In these buried-channel field effect transistors, a parasitic channel is produced at the gate insulating film/Si interface, so the parasitic channel has a major influence on the noise characteristic, as in the case of the SiGe-pMOSFET. Therefore, by applying a potential to the body region (the n-type well 52 or the p-type well 53) so that a forward bias is applied to the semiconductor junction between the body and the source, the number of carriers produced in the parasitic channel can be kept small, and the low-frequency noise characteristic can be improved.

Next, a comparison is made between the SiGe-pMOSFET shown in FIG. 1(b) and the buried-channel pMOSFET (hereinafter referred to as “buried-channel Si-pMOSFET”) shown in FIG. 7(b), which uses the p-type counter doping layer (p-type Si layer) 70. In the case of the buried-channel Si-pMOSFET, when the thickness of the p-type counter doping layer 70 is small, the distance from the gate insulating film 57 to the channel becomes short; thus, the threshold voltage becomes large but the short channel effect becomes small. On the other hand, when the thickness of the p-type counter doping layer 70 is large, the distance from the gate insulating film 57 to the channel becomes long; thus, the threshold voltage becomes small but the short channel effect becomes large. Thus, it is difficult to reduce both the threshold voltage and the short channel effect at the same time. Moreover, since the p-type counter doping layer 70 is formed through an ion implantation method, it has the problem of the impurity diffusion resulting from the thermal process, in addition to the problem that it is technically difficult to perform an extremely shallow implantation to a region of 10 nm or less. In contrast, in the case of the SiGe-pMOSFET, its threshold voltage can be controlled by varying the composition ratio of Ge in the SiGe channel layer 65 and the short channel effect can be suppressed by reducing the film thickness of the Si cap layer 66. Since the Si cap layer 66 can be formed by effecting crystal growth on the SiGe channel layer 65, the film thickness of the Si cap layer 66 can be controlled to be thin by controlling the thickness of the film to be grown. When the crystal growth method of the present example using UHV-CVD equipment, the thickness of the Si cap layer can be reduced to about 0.5 nm. If an atomic layer growth technique is used, the film thickness may be controlled at an atomic layer level. Hence, the SiGe-pMOSFET has the advantage over the buried-channel Si-pMOSFET in that it is easy to reduce both the threshold voltage and the short channel effect at the same time.

In addition, an experiment and a simulation were performed regarding the characteristics of the SiGe-pMOSFET shown in FIG. 1(b). In the experiment and simulation described below, a Si_{0.75}Ge_{0.25} layer was used as the SiGe channel layer 65.

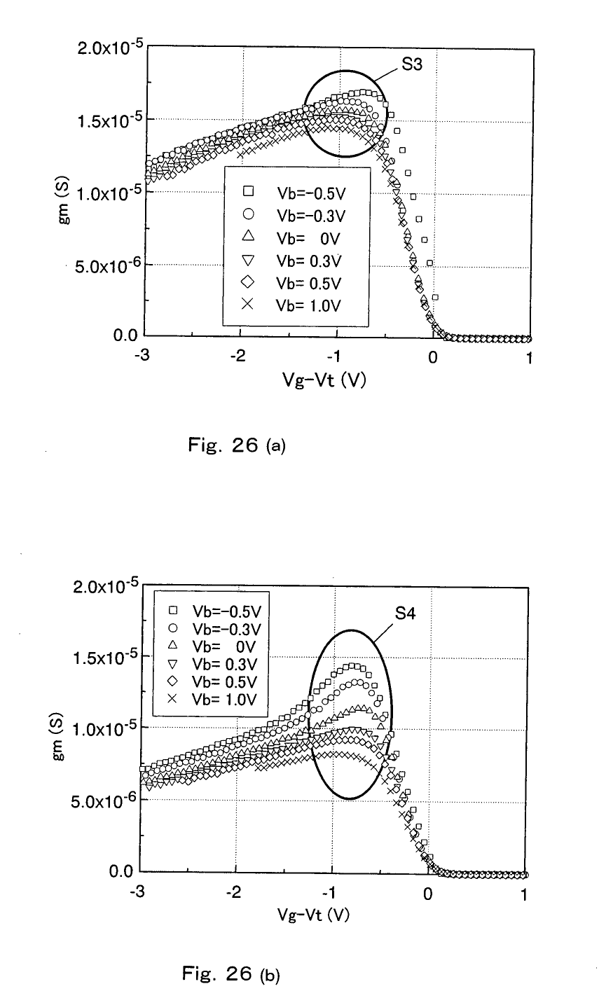

FIG. 26(a) shows measurement results of transconductance (gm) in the case that the film thickness of the Si cap layer 66 of the SiGe-pMOSFET is controlled to be 1 nm, and FIG. 26(b) shows measurement results of transconductance (gm) in the case that the film thickness of the Si cap layer 66 of the SiGe-pMOSFET is controlled to be 6 nm. In both cases of FIG. 26(a) and FIG. 26(b), the device dimensions are; the gate length is 50 μm, and the gate width is 50 μm. The voltage conditions during the measurements are that the drain-source voltage Vd is −300 mV. The horizontal axes represent Vg-Vt, where the gate-source voltage is Vg and the threshold voltage is Vt. Both figures show the measurement results obtained when the body-source voltage Vb applied is varied in a stepwise manner: 1.0 V, 0.5 V, 0.3 V, 0 V, −0.3 V, and −0.5V. As is clear from the comparison between FIG. 26(a), which shows the case that the film thickness of the Si cap layer 66 is 1 nm, and FIG. 26(b), which shows the case that the film thickness of the Si cap layer 66 is 6 nm, the transconductances (gm) are lower when the film thickness of the Si cap layer 66 is thick. In addition, as is clear from the comparison between the S3 portion in FIG. 26(a) and the S4 portion in FIG. 26(b), when the film thickness of the Si cap layer 66 is thick, the transconductance (gm) tends to show a larger variation with respect to the change in the body-source voltage Vb, leading to the problem of unstable device characteristics.

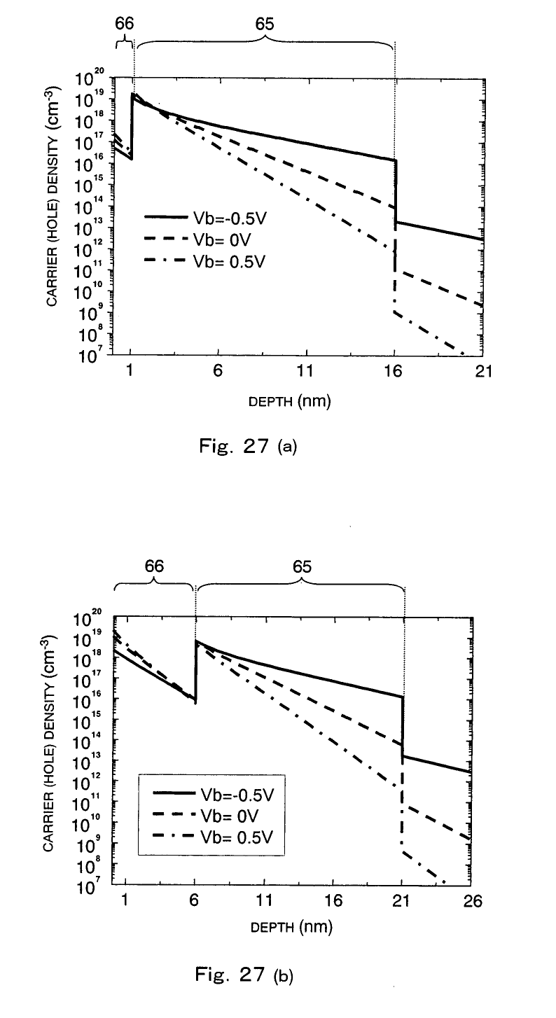

FIG. 27(a) shows the simulation results of carrier density of a region immediately below the gate insulating film 57 of the SiGe-pMOSFET in the case that the film thickness of the Si cap layer 66 is controlled to be 1 nm, and FIG. 27(b) shows the simulation results of carrier density of the region immediately below the gate insulating film 57 of the SiGe-pMOSFET in the case that the film thickness of the Si cap layer 66 is controlled to be 6 nm. Both of FIG. 27(a) and FIG. 27(b) show the simulation results obtained when the body-source voltage Vb is changed in a stepwise manner: 0.5V, 0V, and −0.5V. In both figures, the horizontal axes represent depth from the bottom surface of the gate insulating film 57. As is clear from the comparison between FIG. 27(a) and FIG. 27(b), when the film thickness of the Si cap layer 66 is controlled to be 1 nm, the number of the carriers produced in the Si cap layer 66 are less and more carriers are induced in the SiGe channel layer 65 near the interface with the Si cap layer 66.

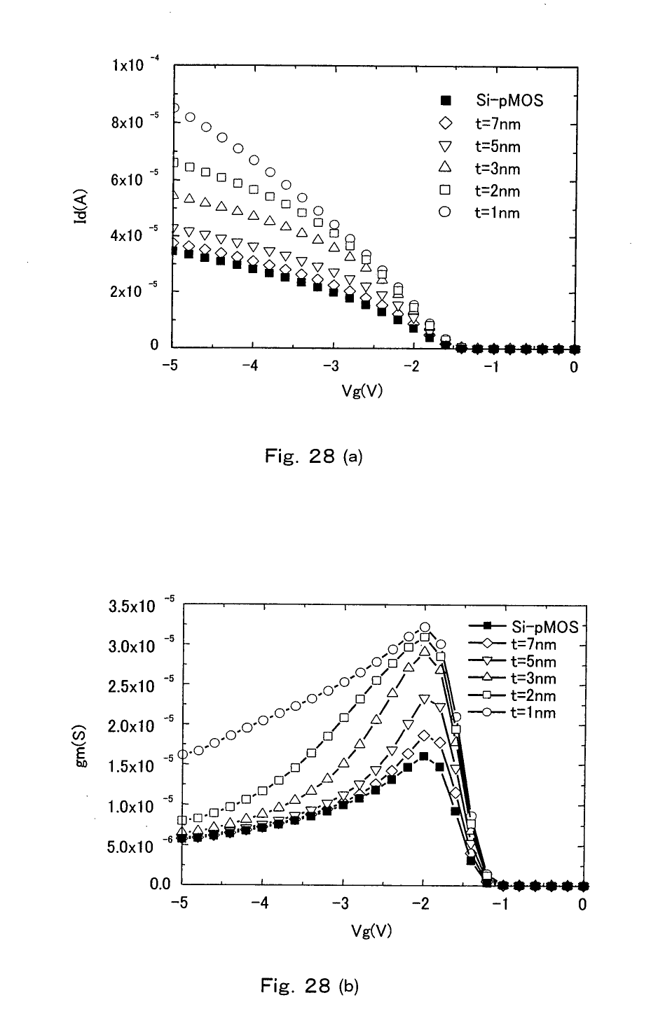

FIG. 28(a) shows the simulation results of drain current Id versus gate-source voltage Vg of the SiGe-pMOSFET, and FIG. 28(b) shows the simulation results of transconductance gm versus gate-source voltage Vg of the SiGe-pMOSFET. In both cases of FIG. 28(a) and FIG. 28(b), the device dimensions were that the gate length was 50 μm and the drain-source voltage Vd was −300 mV. Both figures show the simulation results in the cases that the film thickness (t) of the Si cap layer 66 was controlled to be 1 nm, 2 nm, 3 nm, 5 nm, and 7 nm, and for reference, they also show the results for the surface-channel Si-pMOSFET simulated under the same conditions (Si-pMOS).

As seen from FIGS. 28(a) and 28(b), the thinner the film thickness of the Si cap layer 66 is controlled to be, the greater the drain current Id and the greater the transconductance gm, resulting in improvements in the electrical characteristics. In addition, when the film thickness of the Si cap layer 66 is 7 nm, the electrical characteristics show almost no improvement over the simulation results for the surface-channel Si-pMOSFET (Si-pMOS). Moreover, as seen from FIG. 26(b), when the film thickness of the Si cap layer 66 is 6 nm, the transconductance gm shows a large variation with respect to the change in the body-source voltage Vb. In addition, as seen from FIG. 28(a) and FIG. 28(b), when the film thickness of the Si cap layer 66 is 5 nm, the degree of improvement in the electrical characteristics over the simulation results (Si-pMOS) for the surface-channel Si-pMOSFET is lower. Therefore, it is desirable that the film thickness of the Si cap layer 66 be less than 5 nm. Moreover, in order to achieve the buried channel structure, the Si cap layer 66 is essential. Furthermore, if the film thickness of the Si cap layer 66 is made too thin, there is a risk that germanium oxide may be formed when forming the gate insulating film 57. Formation of germanium oxide leads to an increase in the interface state density, causing problems such as deterioration in low-frequency noise characteristics and shift in the threshold voltage. What is more, segregation of Ge or the like may occur, and an increase in gate leakage current takes place. For the above reasons, it is desirable that the film thickness t of the Si cap layer 66 be controlled to be 0 nm≦t≦5 nm. In addition, as seen from FIG. 28(a) and FIG. 28(b), drain current and transconductance become considerably large when the film thickness of the Si cap layer 66 is 3 nm or less. Therefore, it is desirable that the film thickness of the Si cap layer 66 be less than 3 nm, in order to further improve the electrical characteristics. When Si is exposed to the air, a native oxide film with a thickness of about 1 nm forms. At this time, about 0.5 nm of the Si layer is consumed by the formation of the native oxide film. Therefore, by setting the film thickness of the Si cap layer 66 to be thicker than 0.5 nm, the formation of germanium oxide can be reliably avoided even with the problem of the formation of the native oxide film, which is difficult to control through the process. For the above-described reasons, it is more desirable that the film thickness t of the Si cap layer 66 be 0.5 nm≦t≦3 nm.

Although the foregoing description has illustrated results of the experiments and simulations for the characteristics of the SiGe-pMOSFET shown in FIG. 1(b), it is believed that the buried-channel field effect transistors shown in FIG. 6(a), FIG. 6(b), and FIG. 6(c), each of which having the Si cap layer 66, also show the same tendencies.

Hereinbelow, embodiments of an oscillator that uses a buried-channel MOSFET will be discussed.

### FIRST EMBODIMENT

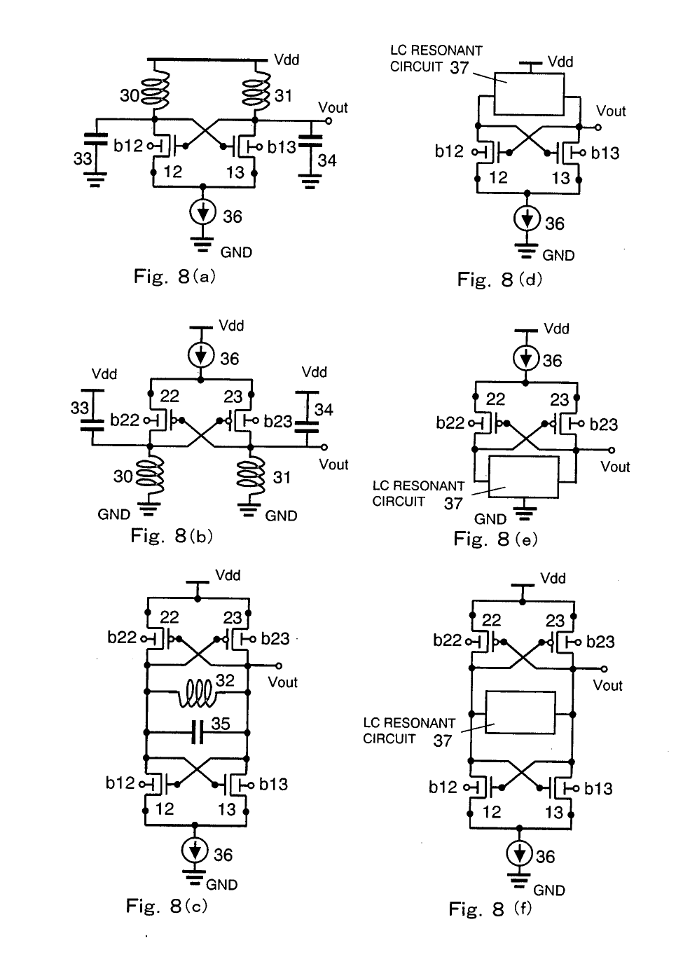

FIG. 8 includes circuit diagrams each illustrating the circuit configuration of an oscillator according to a first embodiment of the present invention. FIG. 8(a) illustrates an example of a cross-coupled differential oscillator that employs the buried-channel nMOSFET, and FIG. 8(d) illustrates a general example of the circuit configuration thereof. This oscillator comprises an LC resonant circuit 37 containing inductors and capacitors as its constituent elements, transistors 12 and 13 composed of nMOSFETs that are differentially connected to each other and the drains of which are connected to the LC resonant circuit 37, a current source 36 connected between the grounded portion (specifically a grounding wire, that is, a lower potential-side power supply wire, to which a ground potential GND is applied) and the portion at which the sources of the transistors 12 and 13 are commonly connected, and an output terminal (Vout is an oscillation output signal) connected to the drain of the transistor 13.

A first feature of this circuit is that the transistors 12 and 13 are buried-channel nMOSFETs, for which one of the buried-channel nMOSFETs as shown in FIG. 6(a), FIG. 6(b), or FIG. 7(a) may be used. A second feature is that the transistors 12 and 13 are provided with body terminals b12 and b13, respectively, for applying a potential to each body region. A signal is amplified by the transistors 12 and 13 which are differentially connected, and the oscillation frequency is determined by the LC resonant circuit 37 comprised of inductors 30 and 31 and capacitors 33 and 34. A potential is applied to each of the body terminals b12 and b13 so that a forward voltage can be applied between the body and the source. In the case where the voltage drop of the current source 36 is represented as Voff, a potential Vb12, which is to be applied to the body terminal b12, and a potential Vb13, which is to be applied to the body terminal b13, should be set so as to satisfy the expression:

Vb12, Vb13>Voff.

It is desirable that the values of Vb12 and Vb13 be controlled to satisfy the expressions:

0.7 volts≧Vb12−Voff, and Vb13−Voff>0.

This is to prevent a forward voltage higher than 0.7 volts, which is equivalent to the diffusion potential (diffusion potential difference) of silicon, from being applied to the semiconductor junction between the body and the source of the buried-channel nMOSFET, and avoid an abrupt current flow from the body region toward the source region. The values (potentials) of Vb12 and Vb13 can be set using external power supplies. The values of Vb12 and Vb13 may be set at the same value (potential). By setting them at the same value (potential), the number of external power supplies required can be reduced.

FIG. 8(b) illustrates an example of a cross-coupled differential oscillator that employs the buried-channel pMOSFET, and FIG. 8(e) illustrates a general example of the circuit configuration thereof. This oscillator comprises an LC resonant circuit 37 containing inductors and capacitors as its constituent elements, transistors 22 and 23 composed of pMOSFETs that are differentially connected to each other and the drains of which are connected to the LC resonant circuit 37, a current source 36 connected between the portion at which the sources of the transistors 22 and 23 are commonly connected and a higher potential-side power supply wire, to which a power supply potential Vdd is applied, and an output terminal (Vout is an oscillation output signal) connected to the drain of the transistor 23.

A first feature of this circuit is that the transistors 22 and 23 are buried-channel pMOSFETs, for which one of the buried-channel pMOSFETs as shown in FIG. 1(b), FIG. 6(c), or FIG. 7(b) may be used. A second feature is that the transistors 22 and 23 are provided with body terminals b22 and b23, respectively, for applying a potential to each body region. A signal is amplified by the transistors 22 and 23 which are differentially connected, and the oscillation frequency is determined by the LC resonant circuit 37 comprised of inductors 30 and 31 and capacitors 33 and 34. A potential is applied to each of the body terminals b22 and b23 so that a forward voltage can be applied between the body and the source. In the case where the power supply voltage is represented as Vdd and the voltage drop of the current source 36 is represented as Voff, a potential Vb22, which is to be applied to the body terminal b22, and a potential Vb23, which is to be applied to the body terminal b23, should be set so as to satisfy the expression:

Vb22, Vb23<Vdd−Voff.

It is desirable that the values of Vb22 and Vb23 be controlled to satisfy the expressions:

0.7 volts≧Vdd−Voff−Vb22, and Vdd−Voff−Vb23>0.

This is to prevent a forward voltage higher than 0.7 volts, which is equivalent to the diffusion potential of silicon, from being applied to the semiconductor junction between the body and the source of the buried-channel pMOSFET, and avoid an abrupt current flow from the source region toward the body region. The values (potentials) of Vb22 and Vb23 can be set using external power supplies. The values of Vb22 and Vb23 may be set at the same value (potential). By setting them at the same value (potential), the number of external power supplies required can be reduced.

FIG. 8(c) illustrates an example of a cross-coupled CMOS differential oscillator that employs the buried-channel nMOSFET and the buried-channel pMOSFET, and FIG. 8(f) illustrates a general example of the circuit configuration thereof. This oscillator comprises an LC resonant circuit 37 containing an inductor and a capacitor as its constituent elements, transistors 22 and 23 composed of pMOSFETs that are differentially connected to each other and the sources of which are connected to a higher potential-side power supply wire, to which a power supply potential Vdd is applied, while the drains of which are connected to the LC resonant circuit 37, transistors 12 and 13 composed of nMOSFETs that are differentially connected to each other and the drains of which are connected to the LC resonant circuit 37, a current source 36 connected between the portion at which the sources of the transistors 12 and 13 are commonly connected and a lower potential-side power supply wire, to which a ground potential GND is applied, and an output terminal (Vout is an oscillation output signal) connected to the drain of the transistor 23.

A first feature of this circuit is that the transistors 12 and 13 are buried-channel nMOSFETs, for which one of the buried-channel nMOSFETs as shown in FIG. 6(a), FIG. 6(b), or FIG. 7(a) may be used. A second feature is that the transistors 22 and 23 are buried-channel pMOSFETs, for which one of the buried-channel pMOSFETs as shown in FIG. 1(b), FIG. 6(c), or FIG. 7(b) may be used. A third feature is that the transistors 12, 13, 22, and 23 are provided with body terminals b12, b13, b22, and b23, respectively, for applying a potential to each body region. A signal is amplified by the transistors 12 and 13 which are differentially connected and by the transistors 22 and 23 which are also differentially connected, and the oscillation frequency is determined by the LC resonant circuit 37 comprised of an inductor 32 and a capacitor 35 and disposed between the two sets of differential circuit pairs. A potential is applied to each of the body terminals b12, b13, b22, and b23 so that a forward voltage can be applied between the body and the source. In the case where the power supply voltage is represented as Vdd and the voltage drop of the current source 36 is represented as Voff, potentials Vb12, Vb13, Vb22, and Vb23, which are applied to the body terminals b12, b13, b22, and b23, respectively, should be set so as to satisfy the expressions:

Vb22, Vb23<Vdd, and

Vb12, Vb13>Voff.

It is desirable that the values of the potentials Vb12, Vb13, Vb22, and Vb23 be controlled to satisfy the expressions:

0.7 volts≧Vb12−Voff, and Vb13−Voff>0; and

0.7 volts≧Vdd−Vb22, and Vdd−Vb23>0.

This is to prevent a forward voltage higher than 0.7 volts, which is equivalent to the diffusion potential of silicon, from being applied to the semiconductor junction between the body and the source of the buried-channel MOSFET, and avoid an abrupt current flow between the body region and the source region. The values (potentials) of Vb12, Vb13, Vb22, and Vb23 can be set using external power supplies. The values of Vb12, Vb13, Vb22, and Vb23 may be set at the same value (potential). By setting them at the same value (potential), the number of external power supplies required can be reduced.

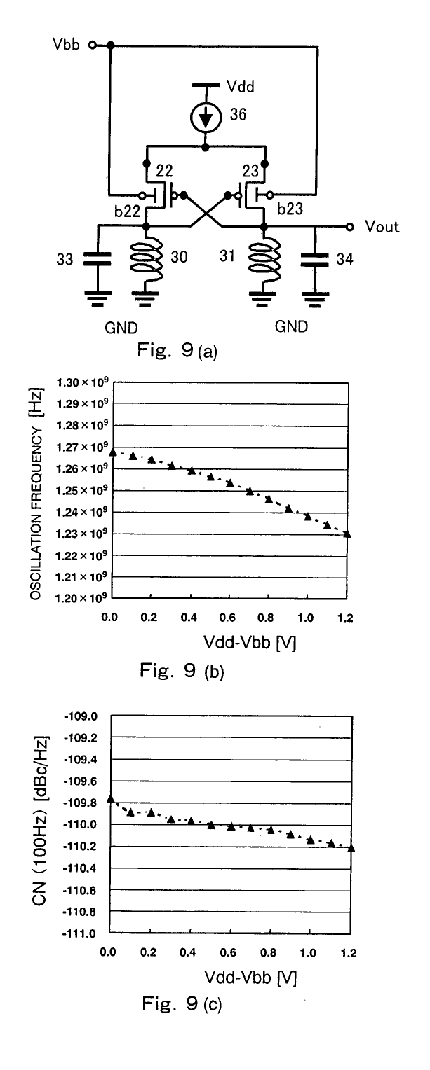

Next, the results of a simulation performed using a circuit simulator will be discussed. This simulation was performed for the transistors of buried channel SiGe-pMOSFETs, and the design parameters for the transistors used were the values extracted from a single transistor of the SiGe-pMOSFET actually produced. FIG. 9(a) is a circuit diagram of an LC oscillator used for the simulation. The dimensions of the transistors 22 and 23 were 0.18 μm in gate length and 500 μm in gate width. The same potential Vbb is applied to the body terminals b22 and b23 of the transistors. The power supply voltage Vdd was set at 1.2 V, and the current value of the current source 36 was set at 16 mA. The inductance of the coils 30 and 31 used in the resonant circuit was set at 2 nH, the capacitance of the capacitors 33 and 34 was 5.6 pF, and the oscillation frequency was set at 1.27 GHz. The quality factor Q of the resonant circuit was set at 5. In FIG. 9(b), the horizontal axis represents source-drain forward voltage (Vdd-Vbb), and FIG. 9(b) shows the dependency of the oscillation frequency on the source-drain forward voltage. Although the oscillation frequency slightly decreases as the source-drain forward voltage value increases, the operation that proves to be acceptable as an oscillator is achieved. In FIG. 9(c), the horizontal axis represents source-drain forward voltage (Vdd-Vbb), and FIG. 9(c) shows the dependency of CN (signal to noise ratio) on the source-drain forward voltage. It will be appreciated that the CN of the circuit is improved by applying a forward voltage between the body and the source.

Thus, according to the present first embodiment, each of the buried-channel field effect transistors that constitute the amplifier circuit of the oscillator has a terminal for applying a potential to the body region, and a potential to be applied to the terminal is set by an external power supply, whereby the voltage value between the body and the source can be arbitrarily set. By applying a potential to the body region so that a forward voltage can be applied to the semiconductor junction between the body and the source, the low-frequency noise characteristic of the field effect transistor for amplification can be reduced, and the noise characteristic of the oscillator as a whole can be improved.

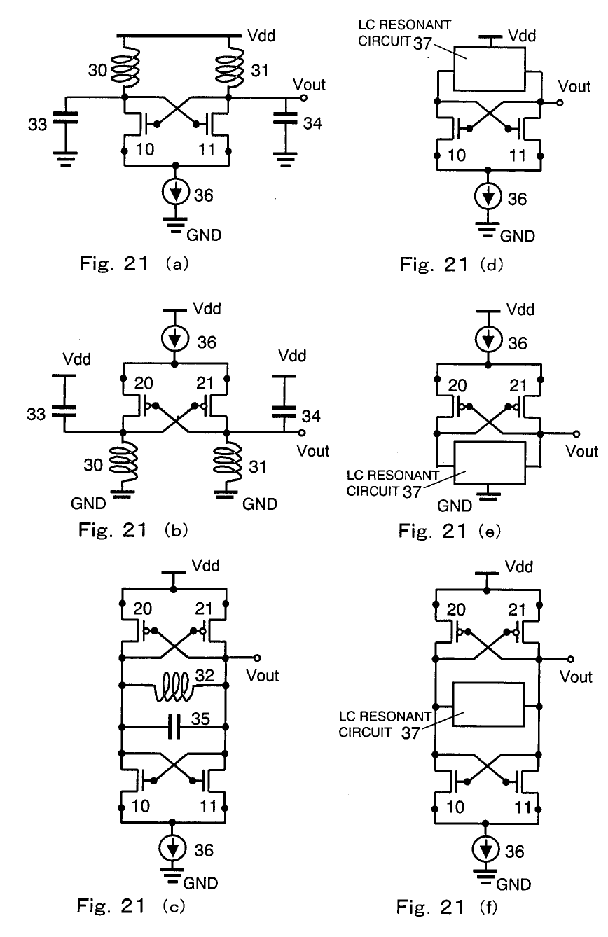

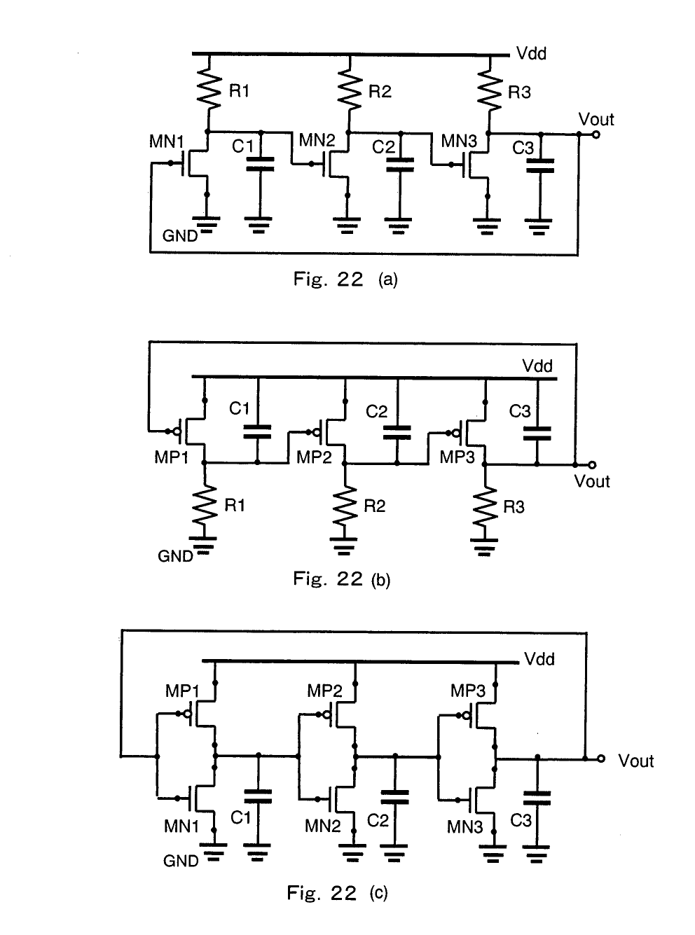

It should be noted that although FIG. 8, which was referred to in the first embodiment, has illustrated examples in which the present invention is applied to cross-coupled differential oscillators shown in FIG. 21, the low-frequency noise characteristics of the field-effect transistors in other oscillators shown in FIG. 22 to FIG. 24 can be improved likewise by applying the present invention thereto. The configurations of these will be explained briefly in the following.

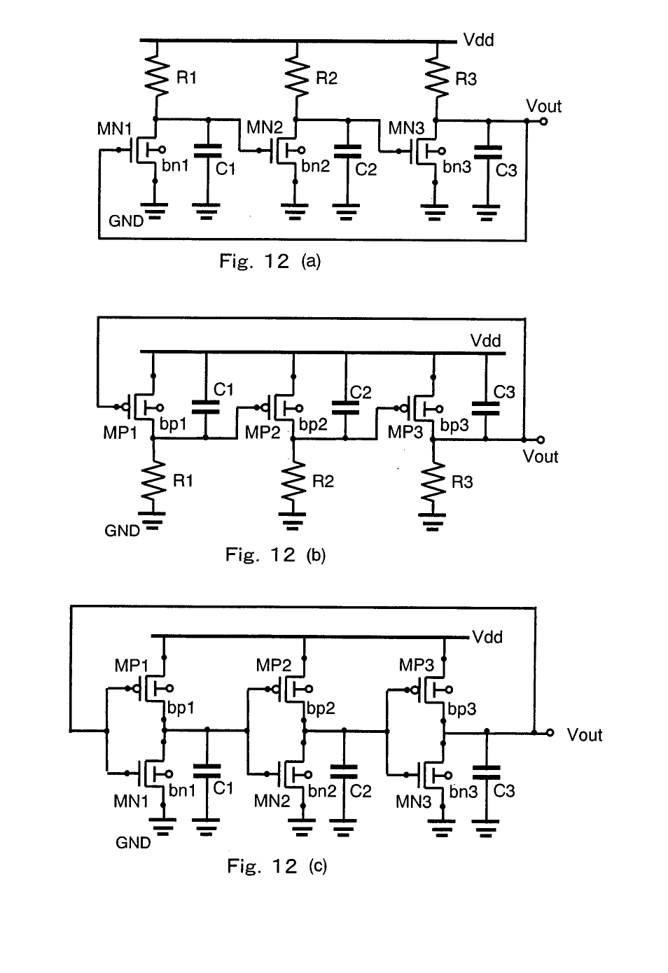

First, FIGS. 12(a), (b), and (c) are circuit diagrams respectively illustrating the circuit configurations in which the present invention is applied to the conventional three-stage single-end ring oscillators shown in FIGS. 22(a), (b), and (c), wherein reference characters bn1 to bn3 represent the body terminals of the nMOSFETs and bp1 to bp3 represent the body terminals of the pMOSFETs. In a three-stage single-end ring oscillator as illustrated in FIG. 12(a) and FIG. 22(a), the first stage portion comprises a resistor R1, one end of which is connected to the higher potential-side power supply wire, and an nMOSFET MN1 and a capacitor C1, which are connected in parallel between the other end of the resistor R1 and a lower potential-side power supply wire. The second stage portion and the third stage portion are configured likewise, and each of the connecting portions of the capacitors and the resistors serves as an output end, which is connected to the gate of the next stage's nMOSFET. The output end of the last stage is connected to the gate of the nMOSFET MN1 of the first stage and also connected to an output terminal (Vout). Moreover, in the case of FIG. 12(a), the following configuration is adopted. As in the case of FIG. 8(a), the buried-channel nMOSFET provided with a body terminal for applying a desired potential to the body region from outside is used for the nMOSFETs MN1 to MN3, and a potential is applied to each of the body terminals bn1 to bn3 so that a forward voltage can be applied to the semiconductor junction between the body and the source. More desirably, the forward voltage applied to the semiconductor junction between the body and the source is controlled to be equal to or lower than the diffusion potential of silicon.

In a three-stage single-end ring oscillator as illustrated in FIG. 12(b) and FIG. 22(b), the first stage portion comprises a resistor R1, one end of which is connected to the lower potential-side power supply wire, and a pMOSFET MP1 and a capacitor C1, which are connected in parallel between the other end of the resistor R1 and the higher potential-side power supply wire. The second stage portion and the third stage portion are configured likewise, and each of the connecting portions of the capacitors and the resistors serves as an output end, which is connected to the gate of the next stage's pMOSFET. The output end of the last stage is connected to the gate of the pMOSFET MP1 of the first stage and also connected to an output terminal (Vout). Moreover, in the case of FIG. 12(b), the following configuration is adopted. As in the case of FIG. 8(b), the buried-channel pMOSFET provided with a body terminal for applying a desired potential to the body region from outside is used for the pMOSFETs MP1 to MP3, and a potential is applied to each of the body terminals bp1 to bp3 so that a forward voltage can be applied to the semiconductor junction between the body and the source. More desirably, the forward voltage applied to the semiconductor junction between the body and the source is controlled to be equal to or lower than the diffusion potential of silicon.

In a three-stage single-end ring oscillator as illustrated in FIG. 12(c) and FIG. 22(c), the first stage portion comprises a pMOSFET MP1 the source of which is connected to the higher potential-side power supply wire, an nMOSFET MN1 the source of which is connected to the lower potential-side power supply wire, the drain of pMOSFET MP1 and the drain of the nMOSFET MN1 being connected to each other, and a capacitor C1 connected between the drain of the pMOSFET MP1 and the lower potential-side power supply wire. The second stage portion and the third stage portion are configured likewise, and each of the connecting portions between the capacitors and the drains of the pMOSFET serves as an output end, which is connected to the gate of the next stage's pMOSFET and the gate of the next stage's nMOSFET. The output end of the last stage is connected to the gates of the pMOSFET MP1 and the nMOSFET MN1 of the first stage, and is also connected to an output terminal (Vout). Moreover, in the case of FIG. 12(c), the following configuration is adopted. As in the case of FIG. 8(c), the buried-channel nMOSFET provided with a body terminal for applying a desired potential to the body region from outside is used for the nMOSFETs MN1 to MN3, and a potential is applied to each of the body terminals bn1 to bn3 so that a forward voltage can be applied to the semiconductor junction between the body and the source. Likewise, the buried-channel pMOSFET provided with a body terminal for applying a desired potential to the body region from outside is used for the pMOSFETs MP1 to MP3, and a potential is applied to each of the body terminals bp1 to bp3 so that a forward voltage can be applied to the semiconductor junction between the body and the source. More desirably, the forward voltage applied to the semiconductor junction between the body and the source is controlled to be equal to or lower than the diffusion potential of silicon. In these cases, as has already been discussed referring to FIG. 22, the number of stages of the transistors (the number of stages of the ring oscillators) is not limited to 3, but may be any odd number equal to or greater than 3.

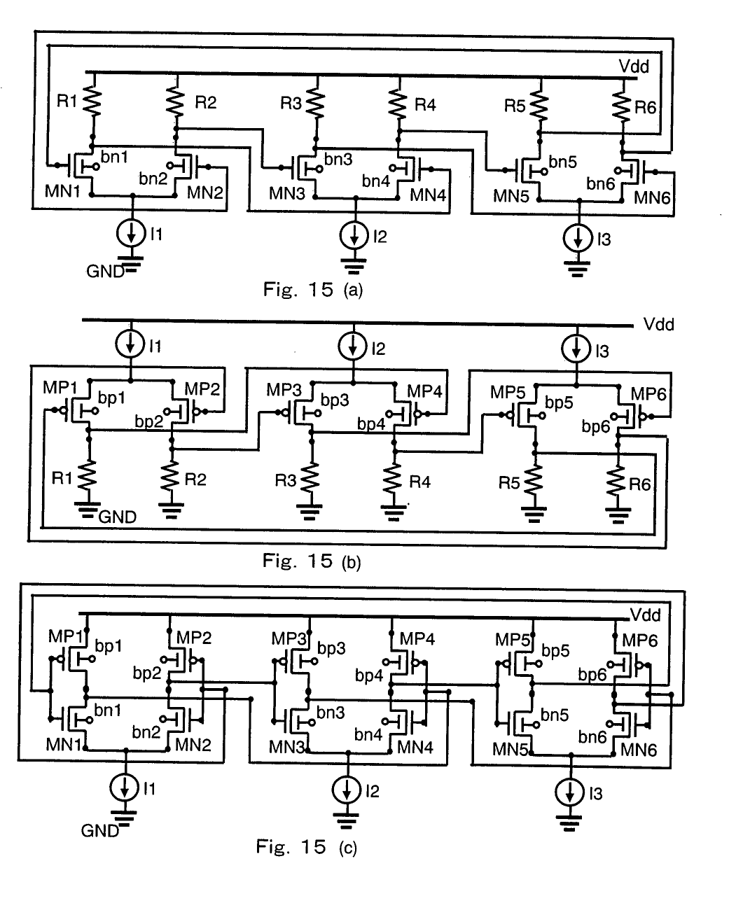

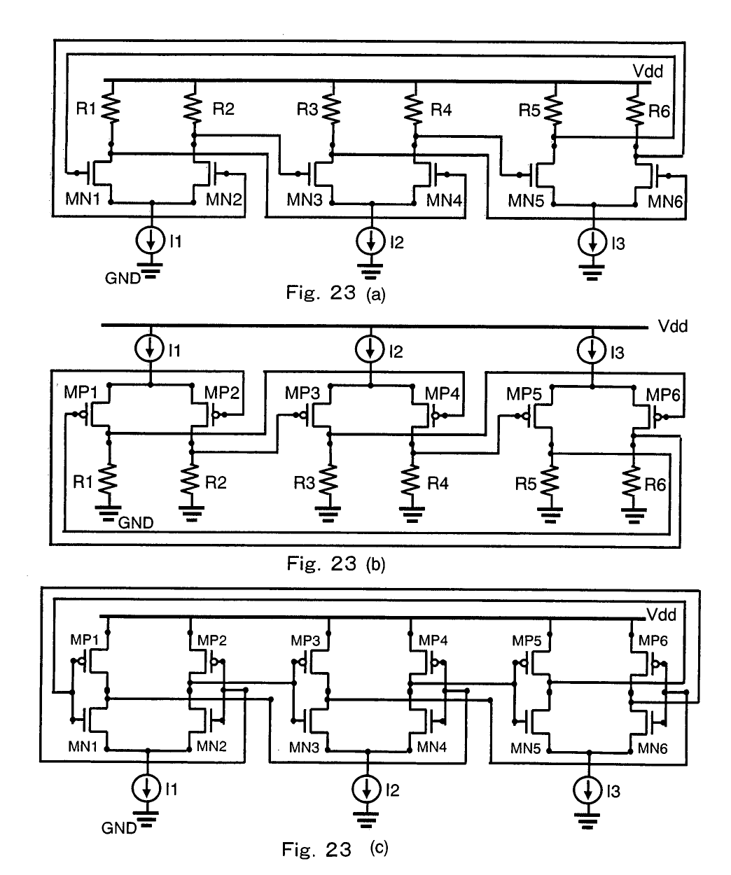

Next, FIGS. 15(a), (b), and (c) are circuit diagrams respectively illustrating the circuit configurations in which the present invention is applied to the conventional differential three-stage ring oscillators shown in FIGS. 23(a), (b), and (c), wherein reference characters bn1 to bn6 represent the body terminals of the nMOSFETs and bp1 to bp6 represent the body terminals of the pMOSFETs. In a differential three-stage ring oscillator as illustrated in FIG. 15(a) and FIG. 23(a), the first stage portion comprises a current source I1 one end of which is connected to the lower potential-side power supply wire, and a resistor R1 and a nMOSFET MN1 which are connected in series between the other end of the current source I1 and a higher potential-side power supply wire, as well as a resistor R2 and a nMOSFET MN2 which are connected in series likewise. The second stage portion and the third stage portion are configured likewise, and each of the drains of the nMOSFETs serves as an output end, which is connected to the gate of the next stage's nMOSFET. The drains of the nMOSFETs MN5 and MN6, which are the output ends of the last stage, are connected to the gates of the nMOSFETs MN1 and MN2 of the first stage, respectively. Moreover, in the case of FIG. 15(a), the following configuration is adopted. As in the case of FIG. 8(a), the buried-channel nMOSFET provided with a body terminal for applying a desired potential to the body region from outside is used for the nMOSFETs MN1 to MN6, and a potential is applied to each of the body terminals bn1 to bn6 so that a forward voltage can be applied to the semiconductor junction between the body and the source. More desirably, the forward voltage applied to the semiconductor junction between the body and the source is controlled to be equal to or lower than the diffusion potential of silicon.

In a differential three-stage ring oscillator as illustrated in FIG. 15(b) and FIG. 23(b), the first stage portion comprises a current source I1 one end of which is connected to the higher potential-side power supply wire, and a resistor R1 and a pMOSFET MP1 which are connected in series between the other end of the current source I1 and a lower potential-side power supply wire, as well as a resistor R2 and a pMOSFET MP2 which are connected in series likewise. The second stage portion and the third stage portion are configured likewise, and each of the drains of the pMOSFETs serves as an output end, which is connected to the gate of each of the next stage's respective pMOSFETs. The drains of the pMOSFETs MP5 and MP6, which are the output ends of the last stage, are connected to the gates of the pMOSFETs MP1 and MP2 of the first stage, respectively. Moreover, in the case of FIG. 15(b), the following configuration is adopted. As in the case of FIG. 8(b), the buried-channel pMOSFET provided with a body terminal for applying a desired potential to the body region from outside is used for the pMOSFETs MP1 to MP6, and a potential is applied to each of the body terminals bp1 to bp6 so that a forward voltage can be applied to the semiconductor junction between the body and the source. More desirably, the forward voltage applied to the semiconductor junction between the body and the source is controlled to be equal to or lower than the diffusion potential of silicon.

In a differential three-stage ring oscillator as illustrated in FIG. 15(c) and FIG. 23(c), the first stage portion comprises a current source I1 one end of which is connected to the lower potential-side power supply wire, an nMOSFET MN1 and a pMOSFET MP1 which are connected in series between the other end of the current source 11 and a higher potential-side power supply wire, as well as an nMOSFET MN1 and a pMOSFET MP2 which are connected in series likewise. The second stage portion and the third stage portion are configured likewise, and the drains of the nMOSFETs (or the drains of the pMOSFETs) serve as output ends, which are connected to the gates of the next stage's nMOSFETs and pMOSFETs. The drain of the nMOSFET MN5 (the drain of the pMOSFET MP5), which is the output end of the last stage, is connected to the gates of the nMOSFETs MN1 and the pMOSFETs MP1 of the first stage. The drain of the nMOSFET MN6 (the drain of the pMOSFET MP6), which is also the output end of the last stage, is connected to the gates of the nMOSFETs MN2 and the pMOSFETs MP2 of the first stage. Moreover, in the case of FIG. 15(c), the following configuration is adopted. As in the case of FIG. 8(c), the buried-channel nMOSFET provided with a body terminal for applying a desired potential to the body region from outside is used for the nMOSFETs MN1 to MN6, and a potential is applied to each of the body terminals bn1 to bn6 so that a forward voltage can be applied to the semiconductor junction between the body and the source. Likewise, the buried-channel pMOSFET provided with a body terminal for applying a desired potential to the body region from outside is used for the pMOSFETs MP1 to MP6, and a potential is applied to each of the body terminals bp1 to bp6 so that a forward voltage can be applied to the semiconductor junction between the body and the source. More desirably, the forward voltage applied to the semiconductor junction between the body and the source is controlled to be equal to or lower than the diffusion potential of silicon. In these cases, as has already been discussed referring to FIG. 23, it is sufficient that the number of stages of the transistor be such that the total number of inversions in the loop is an odd number. The number of stages of the ring oscillators is not limited to 3, but may be either an odd number or an even number that is equal to or greater than 3.

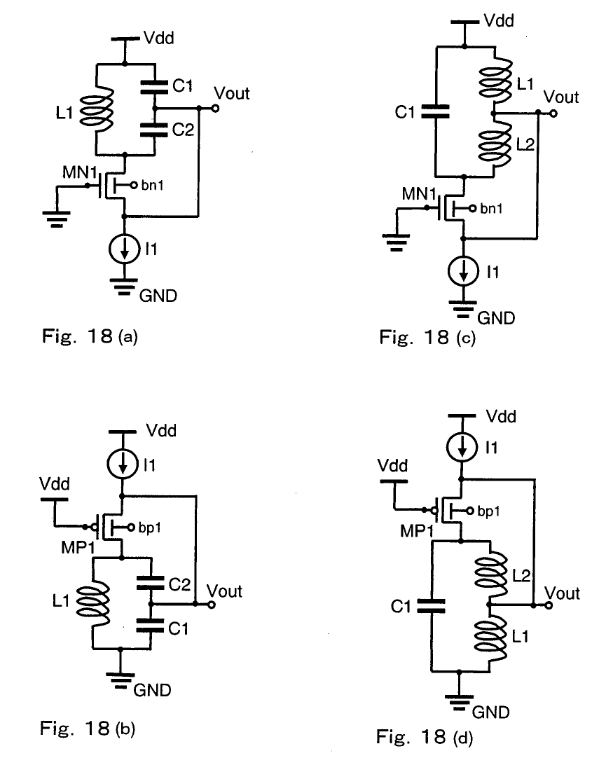

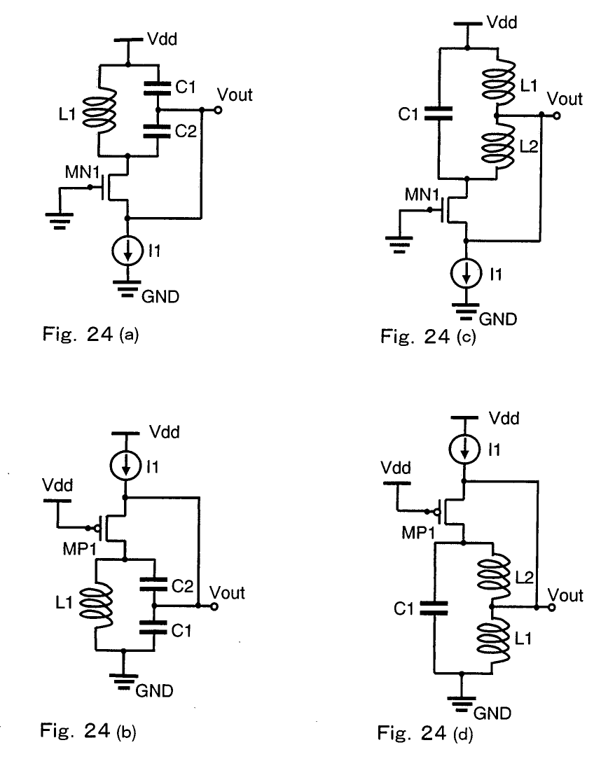

Next, FIGS. 18(a) and (b) are circuit diagrams respectively illustrating the circuit configurations in which the present invention is applied to the conventional Colpitts oscillators shown in FIGS. 24(a) and (b), and FIGS. 18(c) and (d) are circuit diagrams respectively illustrating the circuit configurations in which the present invention is applied to the conventional Hartley oscillators shown in FIGS. 24(c) and (d), wherein reference character bn1 represents the body terminal of the nMOSFET and reference character bp1 represents the body terminal of the pMOSFET. In a Colpitts oscillator as illustrated in FIG. 18(a) and FIG. 24(a), one end of a current source I1 is connected to the lower potential-side power supply wire. The source of an nMOSFET MN1 is connected to the other end of the current source I1, and the gate of the nMOSFET MN1 is connected to the lower potential-side power supply wire. Two capacitors C1 and C2 which are connected in series and an inductor L1 are connected in parallel between the drain of the nMOSFET MN1 and the higher potential-side power supply wire, and the connecting portion of the two capacitors C1 and C2 is connected to the source of the nMOSFET MN1 and an output terminal (Vout). In a Hartley oscillator as illustrated in FIG. 18(c) and FIG. 24(c), one end of a current source I1 is connected to the lower potential-side power supply wire. The source of an nMOSFET MN1 is connected to the other end of the current source I1, and the gate of the nMOSFET MN1 is connected to the lower potential-side power supply wire. Two inductors L1 and L2 which are connected in series and a capacitor C1 are connected in parallel between the drain of the nMOSFET MN1 and the higher potential-side power supply wire, and the connecting portion of the two inductors L1 and L2 is connected to the source of the nMOSFET MN1 and an output terminal (Vout). Moreover, in the cases of FIG. 18(a) and FIG. 18(c), the following configurations are adopted. As in the case of FIG. 8(a), the buried-channel nMOSFET provided with a body terminal for applying a desired potential to the body region from outside is used for the nMOSFET MN1, and a potential is applied to each of the body terminal bn1 so that a forward voltage can be applied to the semiconductor junction between the body and the source. More desirably, the forward voltage applied to the semiconductor junction between the body and the source is controlled to be equal to or lower than the diffusion potential of silicon.

In a Colpitts oscillator as illustrated in FIG. 18(b) and FIG. 24(b), one end of a current source I1 is connected to the higher potential-side power supply wire. The source of a pMOSFET MP1 is connected to the other end of the current source 11, and the gate of the pMOSFET MP1 is connected to the higher potential-side power supply wire. Two capacitors C1 and C2 which are connected in series and an inductor L1 are connected in parallel between the drain of the pMOSFET MP1 and the lower potential-side power supply wire, and the connecting portion of the two capacitors C1 and C2 is connected to the source of the pMOSFET MP1 and an output terminal (Vout). In a Hartley oscillator as illustrated in FIG. 18(d) and FIG. 24(d), one end of a current source 11 is connected to the higher potential-side power supply wire. The source of a pMOSFET MP1 is connected to the other end of the current source I1, and the gate of the pMOSFET MP1 is connected to the higher potential-side power supply wire. Two inductors L1 and L2 which are connected in series and a capacitor C1 are connected in parallel between the drain of the pMOSFET MP1 and the lower potential-side power supply wire, and the connecting portion of the two inductors L1 and L2 is connected to the source of the pMOSFET MP1 and an output terminal (Vout). Moreover, in the cases of FIG. 18(b) and FIG. 18(d), the following configurations are adopted. As in the case of FIG. 8(a), the buried-channel pMOSFET provided with a body terminal for applying a desired potential to the body region from outside is used for the pMOSFET MP1, and a potential is applied to each of the body terminal bp1 so that a forward voltage can be applied to the semiconductor junction between the body and the source. More desirably, the forward voltage applied to the semiconductor junction between the body and the source is controlled to be equal to or lower than the diffusion potential of silicon.

When a p-type Si substrate is used, it is desirable that the buried-channel nMOSFET used in the first embodiment is provided with a triple well structure, although not particularly shown in the drawings. Even when a forward voltage is applied to the body terminal of the buried-channel nMOSFET, effects of the voltage application on the other nMOSFETs disposed on the same substrate can be avoided if using the triple well structure.

### SECOND EMBODIMENT

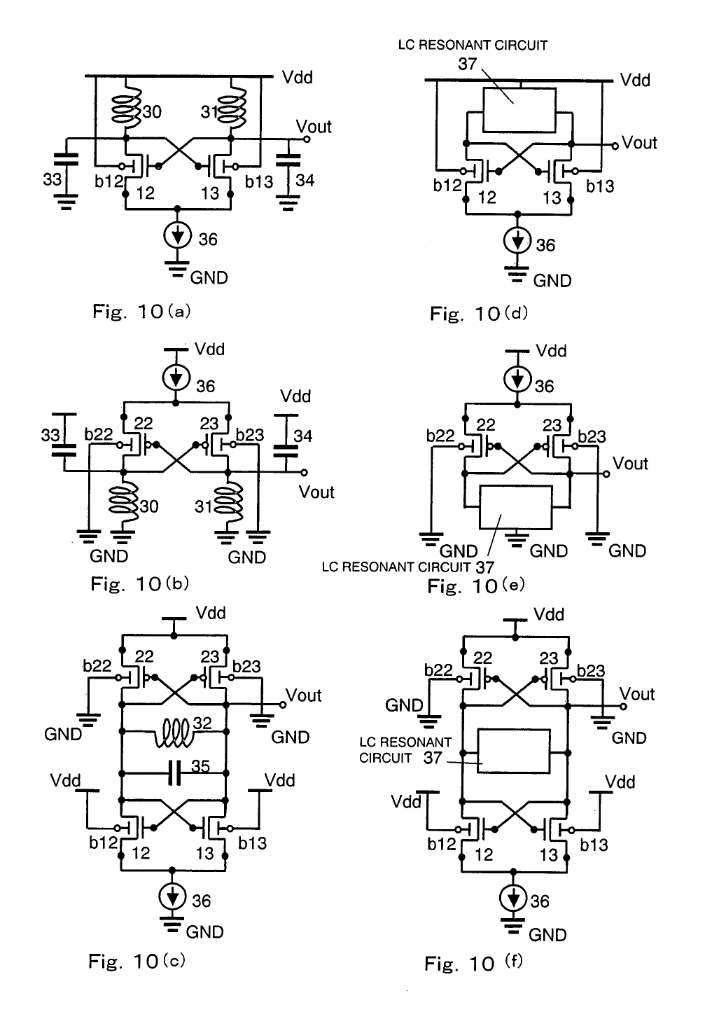

FIG. 10 includes circuit diagrams each illustrating the circuit configuration of an oscillator according to a second embodiment of the present invention. FIG. 10(a) illustrates an example of a cross-coupled differential oscillator that employs the buried-channel nMOSFET, and FIG. 10(d) illustrates a general example of the circuit configuration thereof. A first feature of this circuit is that the transistors 12 and 13 are buried-channel nMOSFETs, for which one of the buried-channel nMOSFETs as shown in FIG. 6(a), FIG. 6(b), or FIG. 7(a) may be used. A second feature is that a power supply potential Vdd is applied to the body terminals b12 and b13 of the transistors 12 and 13. Specifically, the body terminals b12 and b13 are connected to the higher potential-side power supply wire, to which the power supply potential Vdd is applied, using wiring lines.

Here, by connecting the body terminals b12 and b13 to the higher potential-side power supply wire, a forward voltage expressed as:

Vdd−Voff,

where the voltage drop of the current source 36 is represented as Voff, is applied between the body and the source of the buried-channel nMOSFETs. A signal is amplified by the transistors 12 and 13 which are differentially connected, and the oscillation frequency is determined by the LC resonant circuit 37 comprised of inductors 30 and 31 and capacitors 33 and 34. Employing such a circuit configuration has the advantage that the circuit scale can be made smaller than that of the first embodiment because no external power supply is necessary other than the power supply for the power supply voltage Vdd.

In addition, as has been explained with the configuration of FIG. 8(a) in the first embodiment, it is desirable to satisfy the expressions:

0.7 volts≧Vb12−Voff, and Vb13−Voff>0,

and since the values of Vb12 and Vb13 are the power supply potential Vdd here, it is desirable to satisfy the expression:

0.7 volts≧Vdd−Voff>0.

This condition is satisfied, for example, in the case that the voltage drop Voff of the current source 36 is 0.3 V when the power supply voltage Vdd is 1.0 V. A power supply voltage Vdd of 1.0 V can be implemented, for example, in the process rule in which the transistor gate length is controlled to be 65 nm to 90 nm.

It should be noted that the body region of the nMOSFET is usually grounded, so the configuration as shown in FIG. 10(a) in which the body region is connected to the higher potential-side power supply wire is uncommon, and is a distinctive configuration.

FIG. 10(b) illustrates an example of a cross-coupled differential oscillator that employs the buried-channel pMOSFET, and FIG. 10(e) illustrates a general example of the circuit configuration thereof. A first feature of this circuit is that the transistors 22 and 23 are buried-channel pMOSFETs, for which one of the buried-channel pMOSFETs as shown in FIG. 1(b), FIG. 6(c), or FIG. 7(b) may be used. A second feature is that the body terminals b22 and b23 of the transistors 22 and 23 are grounded. Specifically, the body terminals b22 and b23 are connected to the lower potential-side power supply wire (grounding wire), to which a ground potential GND is supplied, using wiring lines.

Here, by grounding the body terminals b22 and b23, a forward voltage expressed as:

Vdd−Voff,

where the voltage drop of the current source 36 is represented as Voff, is applied between the body and the source of the buried-channel pMOSFETs. A signal is amplified by the transistors 22 and 23 which are differentially connected, and the oscillation frequency is determined by the LC resonant circuit 37 comprised of inductors 30 and 31 and capacitors 33 and 34. Employing such a circuit configuration has the advantage that the circuit scale can be made smaller than that of the first embodiment because no external power supply is necessary other than the power supply for the power supply voltage Vdd.

In addition, as has been explained with the configuration of FIG. 8(b) in the first embodiment, it is desirable to satisfy the expressions:

0.7 volts≧Vdd−Voff−Vb22, and Vdd−Voff−Vb23>0,

and since the values of Vb22 and Vb23 are the ground potential 0 V, it is desirable to satisfy the expression:

0.7 volts≧Vdd−Voff>0.

This condition is satisfied, for example, in the case that the voltage drop Voff of the current source 36 is 0.3 V when the power supply voltage Vdd is 1.0 V. A power supply voltage Vdd of 1.0 V can be implemented, for example, in the process rule in which the transistor gate length is controlled to be 65 nm to 90 nm.

It should be noted that the body region of the pMOSFET is usually grounded, so the configuration as shown in FIG. 10(b) in which the body region is connected to the higher potential-side power supply wire is uncommon, and is a distinctive configuration.

FIG. 10(c) illustrates an example of a cross-coupled differential oscillator that employs the buried-channel nMOSFET and the buried-channel pMOSFET, and FIG. 10(f) illustrates a general example of the circuit configuration thereof. A first feature of this circuit is that the transistors 12 and 13 are buried-channel nMOSFETs, for which one of the buried-channel nMOSFETs as shown in FIG. 6(a), FIG. 6(b), or FIG. 7(a) may be used. A second feature is that the transistors 22 and 23 are buried-channel pMOSFETs, for which one of the buried-channel pMOSFETs as shown in FIG. 1(b), FIG. 6(c), or FIG. 7(b) may be used.

A third feature of this circuit is that a power supply potential Vdd is applied to the body terminals b12 and b13 of the transistors 12 and 13. Specifically, the body terminals b12 and b13 are connected to the higher potential-side power supply wire, to which the power supply potential Vdd is applied, using wiring lines. By connecting the body terminals b12 and b13 to the higher potential-side power supply wire, a forward voltage expressed as:

Vdd−Voff,

where the voltage drop of the current source 36 is represented as Voff, is applied between the body and the source of the buried-channel nMOSFETs.

Furthermore, a fourth feature of this circuit is that the body terminals b22 and b23 of the transistors 22 and 23 are grounded. Specifically, the body terminals b22 and b23 are connected to the lower potential-side power supply wire (grounding wire), to which a ground potential GND is supplied, using wiring lines. By grounding the body terminals b22 and b23, a forward voltage expressed as:

Vdd

is applied between the body and the source of the buried-channel pMOSFETs. A signal is amplified by the transistors 12 and 13 which are differentially connected and by the transistors 22 and 23 which are differentially connected in like manner, and the oscillation frequency is determined by the LC resonant circuit 37, which is provided between two pair of differential circuits, comprised of inductors 30 and 31 and capacitors 33 and 34. Employing such a circuit configuration has the advantage that the circuit scale can be made smaller than that of the first embodiment because no external power supply is necessary other than the power supply for the power supply voltage Vdd.

In addition, as has been explained with the configuration of FIG. 8(c) in the first embodiment, it is desirable to satisfy the expressions:

0.7 volts≧Vb12−Voff, and Vb13−Voff>0; and

0.7 volts≧Vdd−Vb22, and Vdd−Vb23>0,

and since the values of Vb12 and Vb13 are the power supply potential Vdd and the values of Vb22 and Vb23 are the ground potential 0 V, it is desirable to satisfy the expressions:

0.7 volts≧Vdd−Voff>0, and

0.7 volts≧Vdd>0.

These conditions are satisfied, for example, when the power supply voltage Vdd is 0.7 V or lower.

Thus, according to the present second embodiment, the low-frequency noise characteristic of the field effect transistor for amplification that is used for oscillators can be reduced, and the noise characteristic of the oscillator as a whole can be improved. In addition, the circuit scale can be made smaller than the first embodiment.

Although FIG. 10, which was referred to in the second embodiment, has illustrated examples in which the present invention is applied to cross-coupled differential oscillators shown in FIG. 21, it should be noted that the same advantageous effects can also be obtained with the other oscillators shown in FIG. 22 to FIG. 24 by applying the present invention thereto. The configurations of these will be explained briefly in the following.

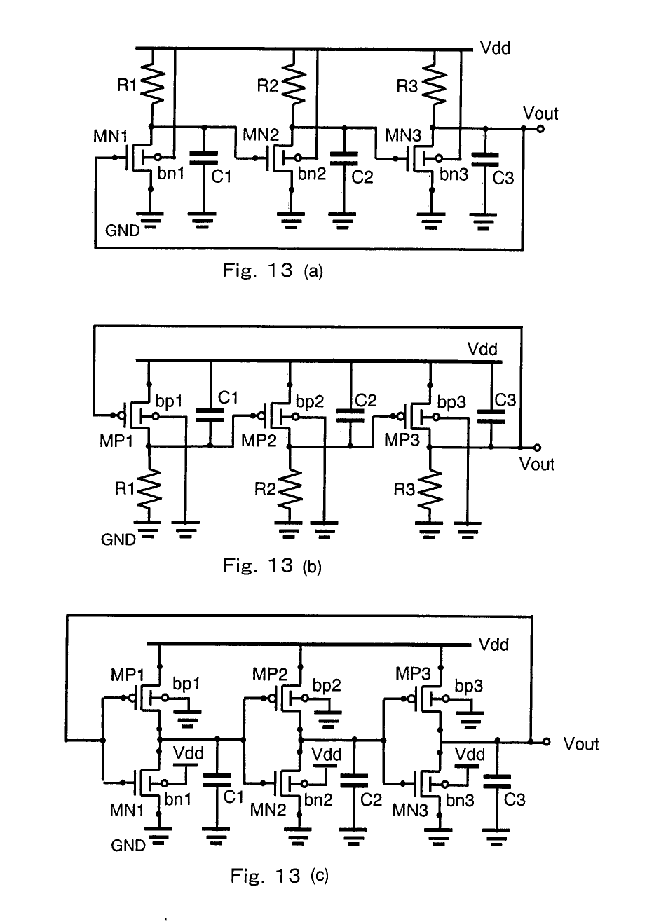

First, FIGS. 13(a), (b), and (c) are circuit diagrams respectively illustrating the circuit configurations in which the present invention is applied to the conventional three-stage single-end ring oscillators shown in FIGS. 22(a), (b), and (c), wherein reference characters bn1 to bn3 represent the body terminals of the nMOSFETs and bp1 to bp3 represent the body terminals of the pMOSFETs. In the case of FIG. 13(a), the following configuration is adopted. As in the case of FIG. 10(a), the buried-channel nMOSFET is used for the nMOSFETs MN1 to MN3, and the body terminals bn1 to bn3 thereof are connected to the higher potential-side power supply wire, to which the power supply potential Vdd is applied, so that a forward voltage can be applied to the semiconductor junction between the body and the source. More desirably, the forward voltage applied to the semiconductor junction between the body and the source is controlled to be equal to or lower than the diffusion potential of silicon. In the case of FIG. 13(b), the following configuration is adopted. As in the case of FIG. 10(b), the buried-channel pMOSFET is used for the pMOSFETs MP1 to MP3, the body terminals bp1 to bp3 are connected to the lower potential-side power supply wire (grounding wire), to which the ground potential GND is applied, so that a forward voltage can be applied to the semiconductor junction between the body and the source. More desirably, the forward voltage applied to the semiconductor junction between the body and the source is controlled to be equal to or lower than the diffusion potential of silicon. In the case of FIG. 13(c), the following configuration is adopted. As in the case of FIG. 10(c), the buried-channel nMOSFET is used for the nMOSFETs MN1 to MN3, and the body terminals bn1 to bn3 thereof are connected to the higher potential-side power supply wire, to which the power supply potential Vdd is applied, so that a forward voltage can be applied to the semiconductor junction between the body and the source. In addition, the buried-channel pMOSFET is used for the pMOSFETs MP1 to MP3, and the body terminals bp1 to bp3 thereof are connected to the lower potential-side power supply wire (grounding wire), to which a ground potential GND is applied, so that a forward voltage can be applied to the semiconductor junction between the body and the source. More desirably, the forward voltage applied to the semiconductor junction between the body and the source is controlled to be equal to or lower than the diffusion potential of silicon. In these cases, as has already been discussed referring to FIG. 22, the number of stages of the transistors is not limited to 3, but may be any odd number equal to or greater than 3.

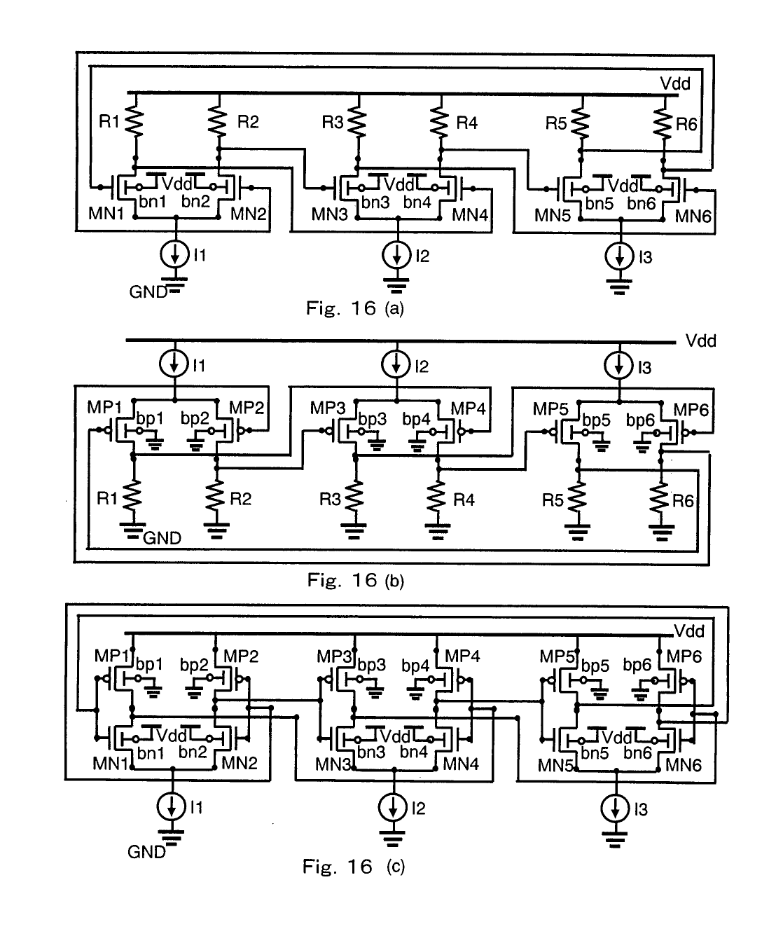

Next, FIGS. 16(a), (b), and (c) are circuit diagrams respectively illustrating the circuit configurations in which the present invention is applied to the conventional differential three-stage ring oscillators shown in FIGS. 23(a), (b), and (c), wherein reference characters bn1 to bn6 represent the body terminals of the nMOSFETs and bp1 to bp6 represent the body terminals of the pMOSFETs. In the case of FIG. 16(a), the following configuration is adopted. As in the case of FIG. 10(a), the buried-channel nMOSFET is used for the nMOSFETs MN1 to MN6, and the body terminals bn1 to bn6 thereof are connected to the higher potential-side power supply wire, to which the power supply potential Vdd is applied, so that a forward voltage can be applied to the semiconductor junction between the body and the source. More desirably, the forward voltage applied to the semiconductor junction between the body and the source is controlled to be equal to or lower than the diffusion potential of silicon. In the case of FIG. 16(b), the following configuration is adopted. As in the case of FIG. 10(b), the buried-channel pMOSFET is used for the pMOSFETs MP1 to MP6, the body terminals bp1 to bp6 are connected to the lower potential-side power supply wire (grounding wire), to which the ground potential GND is applied, so that a forward voltage can be applied to the semiconductor junction between the body and the source. More desirably, the forward voltage applied to the semiconductor junction between the body and the source is controlled to be equal to or lower than the diffusion potential of silicon. In the case of FIG. 16(c), the following configuration is adopted. As in the case of FIG. 10(c), the buried-channel nMOSFET is used for the nMOSFETs MN1 to MN6, and the body terminals bn1 to bn6 thereof are connected to the higher potential-side power supply wire, to which the power supply potential Vdd is applied, so that a forward voltage can be applied to the semiconductor junction between the body and the source. In addition, the buried-channel pMOSFET is used for the pMOSFETs MP1 to MP6, and the body terminals bp1 to bp6 thereof are connected to the lower potential-side power supply wire (grounding wire), to which a ground potential GND is applied, so that a forward voltage can be applied to the semiconductor junction between the body and the source. More desirably, the forward voltage applied to the semiconductor junction between the body and the source is controlled to be equal to or lower than the diffusion potential of silicon. In these cases, as has already been discussed referring to FIG. 23, it is sufficient that the number of stages of the transistor be such that the total number of inversions in the loop is an odd number. The number of stages of the ring oscillators is not limited to 3, but may be either an odd number or an even number that is equal to or greater than 3.

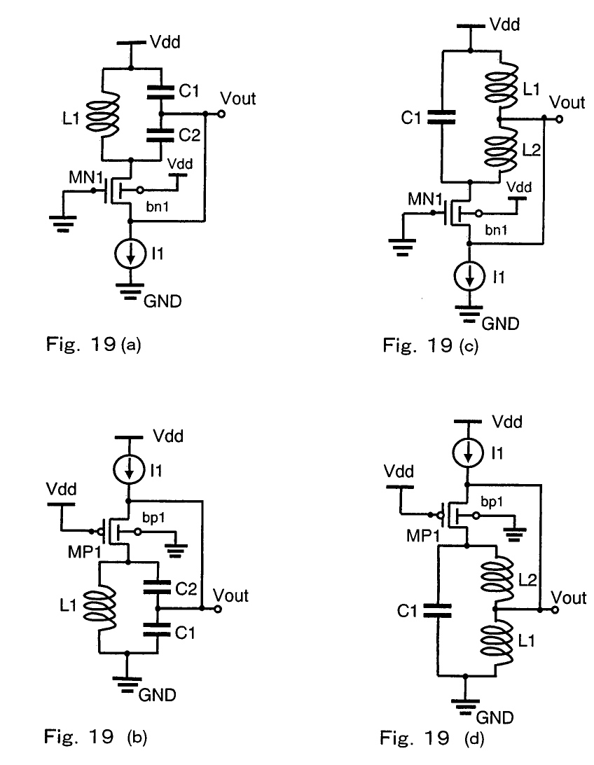

Next, FIGS. 19(a) and (b) are circuit diagrams respectively illustrating the circuit configurations in which the present invention is applied to the conventional Colpitts oscillators shown in FIGS. 24(a) and (b), and FIGS. 19(c) and (d) are circuit diagrams respectively illustrating the circuit configurations in which the present invention is applied to the conventional Hartley oscillators shown in FIGS. 24(c) and (d), wherein reference character bn1 represents the body terminal of the nMOSFET and reference character bp1 represents the body terminal of the pMOSFET. In the cases of FIG. 19(a) and FIG. 19(c), the following configurations are adopted. As in the case of FIG. 10(a), the buried-channel nMOSFET is used for the nMOSFET MN1, and the body terminal bn1 is connected to the higher potential-side power supply wire, to which the power supply potential Vdd is applied, so that a forward voltage can be applied to the semiconductor junction between the body and the source. More desirably, the forward voltage applied to the semiconductor junction between the body and the source is controlled to be equal to or lower than the diffusion potential of silicon. In the cases of FIG. 19(b) and FIG. 19(d), the following configurations are adopted. As in the case of FIG. 10(b), the buried-channel pMOSFET is used for the pMOSFET MP1, and the body terminal bp1 is connected to the lower potential-side power supply wire (grounding wire), to which the ground potential GND is applied, so that a forward voltage can be applied to the semiconductor junction between the body and the source. More desirably, the forward voltage applied to the semiconductor junction between the body and the source is controlled to be equal to or lower than the diffusion potential of silicon.

When a p-type Si substrate is used, it is desirable that the buried-channel nMOSFET used in the second embodiment is provided with a triple well structure, although not particularly shown in the drawings. Even when a forward voltage is applied to the body terminal of the buried-channel nMOSFET, effects of the voltage application on the other nMOSFETs disposed on the same substrate can be avoided if using the triple well structure.

### THIRD EMBODIMENT

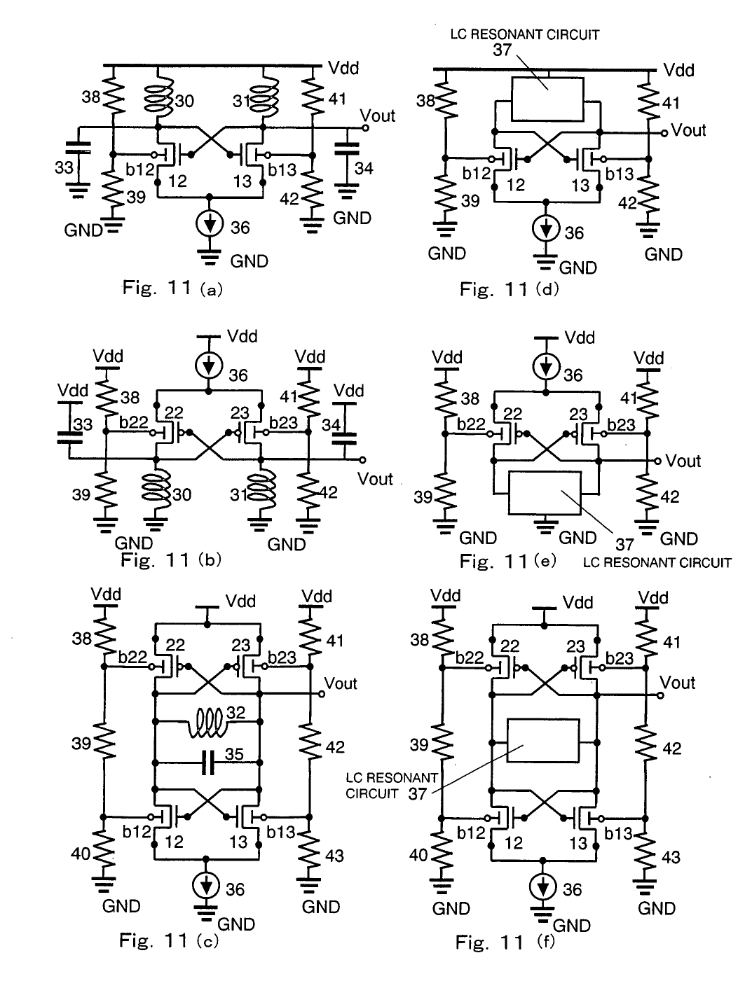

FIG. 11 includes circuit diagrams each illustrating the circuit configuration of an oscillator according to a third embodiment of the present invention. FIG. 11(a) illustrates an example of a cross-coupled differential oscillator that employs the buried-channel nMOSFET, and FIG. 11(d) illustrates a general example of the circuit configuration thereof. A first feature of this circuit is that the transistors 12 and 13 are buried-channel nMOSFETs, for which one of the buried-channel nMOSFETs as shown in FIG. 6(a), FIG. 6(b), or FIG. 7(a) may be used. A second feature of this circuit is that resistors 38 and 39 are connected to the body terminal b12 of the transistor 12 so that a potential equivalent to a voltage value obtained by resistively dividing the power supply voltage Vdd is applied to the body terminal b12. The resistors 38 and 39 are connected in series between the higher potential-side power supply wire, to which the power supply potential Vdd is applied, and the lower potential-side power supply wire (grounding wire), to which the ground potential GND is applied. When the body-source resistance component of the transistor 12 is sufficiently larger than a resistance value r1 of the resistor 38 and a resistance value r2 of the resistor 39, a potential expressed as:

Vdd×r2/(r1+r2)

is applied to the body terminal b12 by the resistors 38 and 39. At this time, a forward voltage expressed as:

Vdd×r2/(r1+r2)−Voff,

where the voltage drop in the current source 36 is represented as Voff, is applied between the body and the source of the transistor 12.

A third feature of this circuit is that resistors 41 and 42 are connected to the body terminal b13 of the transistor 13 so that a potential equivalent to a voltage value obtained by resistively dividing the power supply voltage Vdd is applied to the body terminal b13. The resistors 41 and 42 are connected in series between the higher potential-side power supply wire and the lower potential-side power supply wire (grounding wire). When the body-source resistance component of the transistor 13 is sufficiently larger than a resistance value r3 of the resistor 41 and a resistance value r4 of the resistor 42, a potential expressed as:

Vdd×r4/(r3+r4)

is applied to the body terminal b13 by the resistors 41 and 42. At this time, a forward voltage expressed as:

Vdd×r4/(r3+r4)−Voff,

where the voltage drop in the current source 36 is represented as Voff, is applied between the body and the source of the transistor 13. When the forward voltage applied between the body and the source becomes higher than about 0.7 V, which is equivalent to the diffusion potential of silicon, electric current flows between the body and the source since the body-source resistance component becomes small (the diode is turned on). Accordingly, it is desirable that the values of r1, r2, r3 and r4 be set so that the forward voltage applied between the body and the source becomes about 0.7 V or lower. For example, in the process rule currently used, in which the gate length is set at 0.13 μm, the power supply voltage Vdd is usually set at 1.2 V.

If the resistances are set as:

r1=r2=r3=r4=12 kΩ,

and Voff is assumed to be sufficiently small, a potential of 0.6 V is applied to the body regions of the transistors 12 and 13, and the source-drain forward voltage becomes 0.6 V, which satisfies the condition of 0.7 V or lower. In addition, the current value flowing through all the resistors is 100 μA, accordingly it can make the current value be sufficiently smaller than the current flowing through the current source. Furthermore, by setting the four resistance values to be the same value, variations in the divided voltage values can also be reduced.

FIG. 11(b) illustrates an example of a cross-coupled differential oscillator that employs the buried-channel pMOSFET, and FIG. 10(e) illustrates a general example of the circuit configuration thereof. A first feature of this circuit is that the transistors 22 and 23 are buried-channel pMOSFETs, for which one of the buried-channel pMOSFETs as shown in FIG. 1(b), FIG. 6(c), or FIG. 7(b) may be used.

A second feature of this circuit is that resistors 38 and 39 are connected to the body terminal b22 of the transistor 22 so that a potential equivalent to a voltage value obtained by resistively dividing the power supply voltage Vdd is applied to the body terminal b22. The resistors 38 and 39 are connected in series between the higher potential-side power supply wire and the lower potential-side power supply wire (grounding wire). When the body-source resistance component of the transistor 22 is sufficiently larger than a resistance value r1 of the resistor 38 and a resistance value r2 of the resistor 39, a potential expressed as:

Vdd×r2/(r1+r2)

is applied to the body terminal b22 by the resistors 38 and 39. At this time, a forward voltage expressed as:

Vdd×r1/(r1+r2)−Voff

where the voltage drop in the current source 36 is represented as Voff, is applied between the body and the source of the transistor 22.

A third feature of this circuit is that resistors 41 and 42 are connected to the body terminal b23 of the transistor 23 so that a potential equivalent to a voltage value obtained by resistively dividing the power supply voltage Vdd is applied to the body terminal b23. The resistors 41 and 42 are connected in series between the higher potential-side power supply wire and the lower potential-side power supply wire (grounding wire). When the body-source resistance component of the transistor 23 is sufficiently larger than a resistance value r3 of the resistor 41 and a resistance value r4 of the resistor 42, a potential expressed as:

Vdd×r4/(r3+r4)

is applied to the body terminal 23 by the resistors 41 and 42. At this time, a forward voltage expressed as:

Vdd×r3/(r3+r4)−Voff,

where the voltage drop in the current source 36 is represented as Voff, is applied between the body and the source of the transistor 23. When the forward voltage applied between the body and the source becomes higher than about 0.7 V, which is equivalent to the diffusion potential of silicon, electric current flows between the body and the source since the body-source resistance component becomes small (the diode is turned on). Accordingly, it is desirable that the values of r1, r2, r3 and r4 be set so that the forward voltage applied between the body and the source becomes about 0.7 V or lower.

FIG. 11(c) illustrates an example of a cross-coupled differential oscillator that employs the buried-channel nMOSFET and the buried-channel pMOSFET, and FIG. 11(f) illustrates a general example of the circuit configuration thereof. A first feature of this circuit is that the transistors 12 and 13 are buried-channel nMOSFETs, for which one of the buried-channel nMOSFETs as shown in FIG. 6(a), FIG. 6(b), or FIG. 7(a) may be used. A second feature is that the transistors 22 and 23 are buried-channel pMOSFETs, for which one of the buried-channel pMOSFETs as shown in FIG. 1(b), FIG. 6(c), or FIG. 7(b) may be used.

A third feature of this circuit is that resistors 38, 39, and 40 are connected to the body terminals b12 and b22 of the transistors 12 and 22 so that a potential equivalent to a voltage value obtained by resistively dividing the power supply voltage Vdd is applied to the body terminals b12 and b22. The resistors 38, 39, and 40 are connected in series between the higher potential-side power supply wire and the lower potential-side power supply wire (grounding wire). When the body-source resistance components of the transistors 11 and 22 are sufficiently larger than a resistance value r1 of the resistor 38, a resistance value r2 of the resistor 39, and a resistance value r3 of the resistor 40, a potential expressed as:

Vdd×r3/(r1+r2+r3)

is applied to body terminal b12, while a potential expressed as:

Vdd×(r2+r3)/(r1+r2+r3)

is applied to the body terminal b22. At this time, a forward voltage expressed as:

Vdd×r3/(r1+r2+r3)−Voff

where the voltage drop in the current source 36 is represented as Voff, is applied between the body and the source of the transistor 12, while a forward voltage expressed as:

Vdd×r1/(r1+r2+r3)

is applied between the body and the source of the transistor 22.

A fourth feature of this circuit is that resistors 41, 42 and 43 are connected to the body terminals b13 and b23 of the transistors 13 and 23 so that a potential equivalent to a voltage value obtained by resistively dividing the power supply voltage Vdd is applied to the body terminals b13 and b23. The resistors 38, 39, and 40 are connected in series between the higher potential-side power supply wire and the lower potential-side power supply wire (grounding wire). When the body-source resistance components of the transistors 13 and 23 are sufficiently larger than a resistance value r4 of the resistor 41, a resistance value r5 of the resistor 42, and a resistance value r6 of the resistor 43, a potential expressed as:

Vdd×r6/(r4+r5+r6)

is applied to body terminal b13, while a potential expressed as:

Vdd×(r5+r6)/(r4+r5+r6)

is applied to the body terminal b23. At this time, a forward voltage expressed as:

Vdd×r6/(r4+r5+r6)−Voff,

where the voltage drop in the current source 36 is represented as Voff, is applied between the body and the source of the transistor 13, while a forward voltage expressed as:

Vdd×r4/(r4+r5+r6)

is applied between the body and the source of the transistor 23. When the forward voltage applied between the body and the source becomes higher than about 0.7 V, which is equivalent to the diffusion potential of silicon, electric current flows between the body and the source since the body-source resistance component becomes small (the diode is turned on). Accordingly, it is desirable that the values of r1, r2, r3, r4, r5, and r6 be set so that the forward voltage applied between the body and the source becomes about 0.7 V or lower.

Thus, according to the present third embodiment, the low-frequency noise characteristic of the field effect transistor for amplification that is used in the oscillator can be reduced, and the noise characteristic of the oscillator as a whole can be improved. Moreover, the forward voltage applied between the body and the source can be arbitrarily set according to the relationships between the resistance values of the resistors, using a resistive potential divider circuit as a potential-applying means to the body terminal.

Although FIG. 11, which was referred to in the second embodiment, has illustrated examples in which the present invention is applied to cross-coupled differential oscillators shown in FIG. 21, it should be noted that the same advantageous effects can also be obtained with the other oscillators shown in FIG. 22 to FIG. 24 by applying the present invention thereto. The configurations of these will be explained briefly in the following.

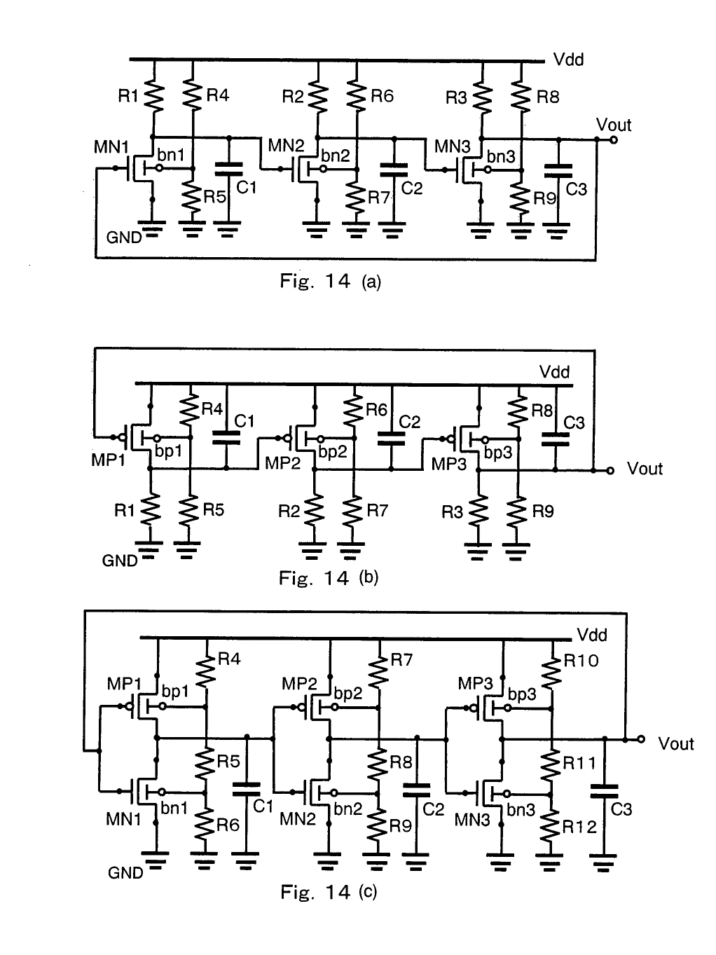

First, FIGS. 14(a), (b), and (c) are circuit diagrams respectively illustrating the circuit configurations in which the present invention is applied to the conventional three-stage single-end ring oscillators shown in FIGS. 22(a), (b), and (c), wherein reference characters bn1 to bn3 represent the body terminals of the nMOSFETs, reference characters bp1 to bp3 represent the body terminals of the pMOSFETs, and R4 to R12 represent the resistors that constitute the resistive potential divider circuit. In the case of FIG. 14(a), the following configuration is adopted. Resistors R4 and R5, R6 and R7, and R8 and R9 constitute respective resistive potential divider circuits. As in the case of FIG. 11(a), the buried-channel nMOSFET is used for the nMOSFETs MN1 to MN3, and a potential equivalent to a voltage value obtained by resistively dividing the power supply voltage Vdd is applied from the respective resistive potential divider circuits to the body terminals bn1 to bn3 thereof so that a forward voltage can be applied to the semiconductor junction between the body and the source. More desirably, the resistance values are set so that the forward voltage applied to the semiconductor junction between the body and the source becomes equal to or lower than the diffusion potential of silicon. In the case of FIG. 14(b), the following configuration is adopted. Resistors R4 and R5, R6 and R7, and R8 and R9 constitute respective resistive potential divider circuits. As in the case of FIG. 11(b), the buried-channel pMOSFET is used for the pMOSFETs MP1 to MP3, and a potential equivalent to a voltage value obtained by resistively dividing the power supply voltage Vdd is applied from the respective resistive potential divider circuits to the body terminals bp1 to bp3 so that a forward voltage can be applied to the semiconductor junction between the body and the source. More desirably, the resistance values are set so that the forward voltage applied to the semiconductor junction between the body and the source becomes equal to or lower than the diffusion potential of silicon. In the case of FIG. 14(c), the following configuration is adopted. Resistors R4, R5 and R6; R7, R8 and R9; and R10, R11 and R12 constitute respective resistive potential divider circuits. As in the case of FIG. 11(c), the buried-channel nMOSFET is used for the nMOSFETs MN1 to MN3, and a potential equivalent to a voltage value obtained by resistively dividing the power supply voltage Vdd is applied from the respective resistive potential divider circuits to the body terminals bn1 to bn3 thereof so that a forward voltage can be applied to the semiconductor junction between the body and the source. In addition, the buried-channel pMOSFET is used for the pMOSFETs MP1 to MP3, and a potential equivalent to a voltage value obtained by resistively dividing the power supply voltage Vdd is applied from the respective resistive potential divider circuits to the body terminals bp1 to bp3 thereof so that a forward voltage can be applied to the semiconductor junction between the body and the source. More desirably, the resistance values are set so that the forward voltage applied to the semiconductor junction between the body and the source becomes equal to or lower than the diffusion potential of silicon. In these cases, as has already been discussed referring to FIG. 22, the number of stages of the transistors (the number of stages of the ring oscillators) is not limited to 3, but may be any odd number equal to or greater than 3.

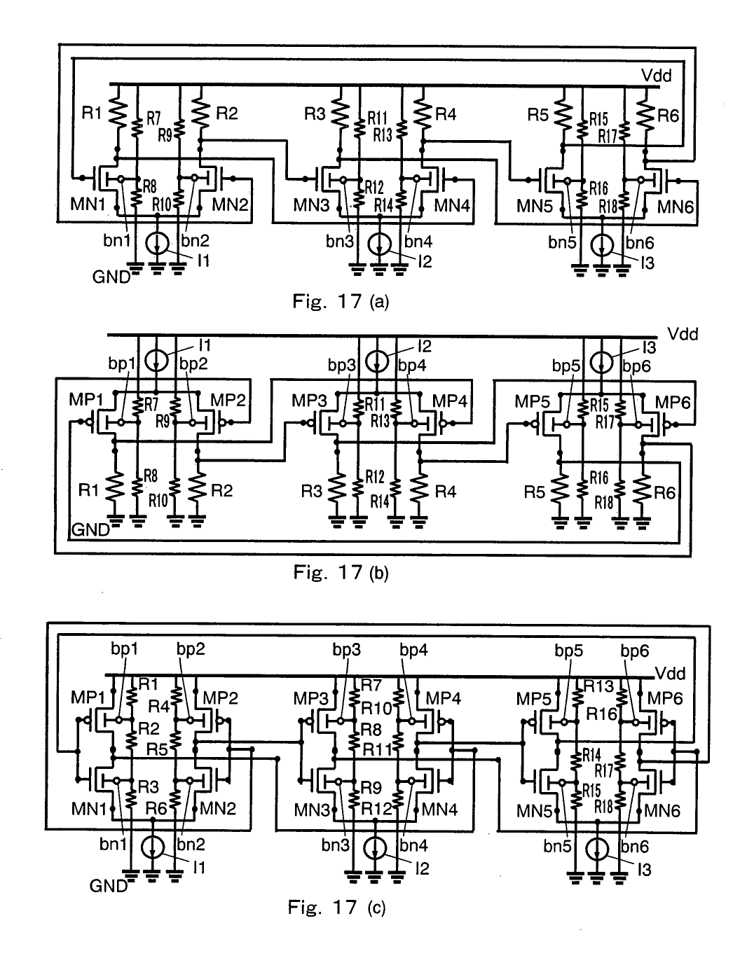

Next, FIGS. 17(a), (b), and (c) are circuit diagrams respectively illustrating the circuit configurations in which the present invention is applied to the conventional differential three-stage ring oscillators shown in FIGS. 23(a), (b), and (c), wherein reference characters bn1 to bn6 represent the body terminals of the nMOSFETs and bp1 to bp6 represent the body terminals of the pMOSFETs. In the case of FIG. 17(a), the following configuration is adopted. Resistors R7 and R8, R9 and R10, R11 and R12, R13 and R14, R15 and R16, and R17 and R18 constitute respective resistive potential divider circuits. As in the case of FIG. 11(a), the buried-channel nMOSFET is used for the nMOSFETs MN1 to MN6, and a potential equivalent to a voltage value obtained by resistively dividing the power supply voltage Vdd is applied from the respective resistive potential divider circuits to the body terminals bn1 to bn6 thereof so that a forward voltage can be applied to the semiconductor junction between the body and the source. More desirably, the resistance values are set so that the forward voltage applied to the semiconductor junction between the body and the source becomes equal to or lower than the diffusion potential of silicon. In the case of FIG. 17(b), the following configuration is adopted. Resistors R7 and R8, R9 and R10, R11 and R12, R13 and R14, R15 and R16, and R17 and R18 constitute respective resistive potential divider circuits. As in the case of FIG. 11(b), the buried-channel pMOSFET is used for the pMOSFETs MP1 to MP6, and a potential equivalent to a voltage value obtained by resistively dividing the power supply voltage Vdd is applied from the respective resistive potential divider circuits to the body terminals bp1 to bp6 thereof so that a forward voltage can be applied to the semiconductor junction between the body and the source. More desirably, the resistance values are set so that the forward voltage applied to the semiconductor junction between the body and the source becomes equal to or lower than the diffusion potential of silicon. In the case of FIG. 17(c), the following configuration is adopted. Resistors R1, R2 and R3; R4, R5 and R6; R7, R8 and R9; R10, R11 and R12; R13, R14 and R15; and R16, R17 and R18 constitute respective resistive potential divider circuits. As in the case of FIG. 11(c), the buried-channel nMOSFET is used for the nMOSFETs MN1 to MN6, and a potential equivalent to a voltage value obtained by resistively dividing the power supply voltage Vdd is applied from the respective resistive potential divider circuits to the body terminals bn1 to bn6 thereof so that a forward voltage can be applied to the semiconductor junction between the body and the source. In addition, the buried-channel pMOSFET is used for the pMOSFETs MP1 to MP6, and a potential equivalent to a voltage value obtained by resistively dividing the power supply voltage Vdd is applied from the respective resistive potential divider circuits to the body terminals bp1 to bp6 thereof so that a forward voltage can be applied to the semiconductor junction between the body and the source. More desirably, the resistance values are set so that the forward voltage applied to the semiconductor junction between the body and the source becomes equal to or lower than the diffusion potential of silicon. In these cases, as has already been discussed referring to FIG. 23, it is sufficient that the number of stages of the transistor be such that the total number of inversions in the loop is an odd number. The number of stages of the ring oscillators is not limited to 3, but may be either an odd number or an even number that is equal to or greater than 3.

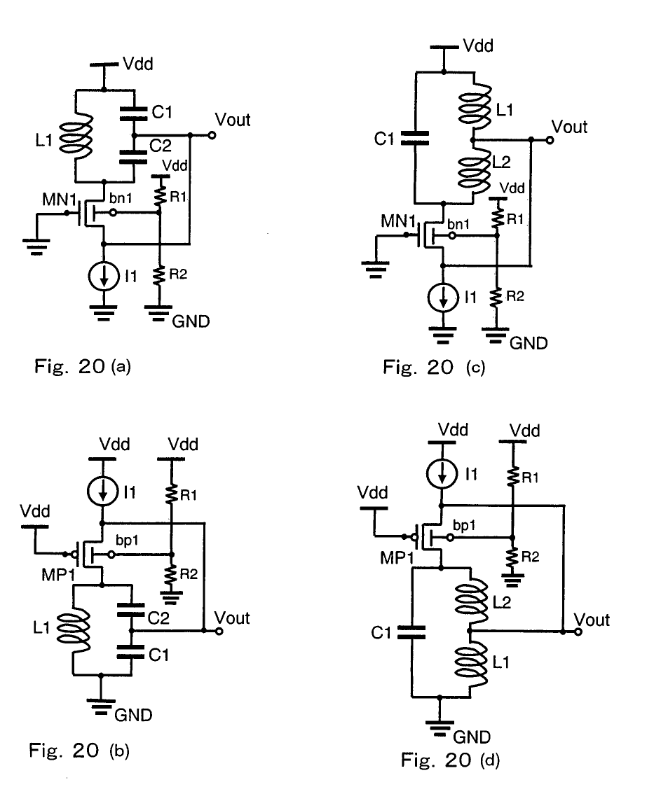

Next, FIGS. 20(a) and (b) are circuit diagrams respectively illustrating the circuit configurations in which the present invention is applied to the conventional Colpitts oscillators shown in FIGS. 24(a) and (b), and FIGS. 20(c) and (d) are circuit diagrams respectively illustrating the circuit configurations in which the present invention is applied to the conventional Hartley oscillators shown in FIGS. 24(c) and (d), wherein reference character bn1 represents the body terminal of the nMOSFET, reference character bp1 represents the body terminal of the pMOSFET, and reference characters R1 and R2 represent resistors that constitute a resistive potential divider circuit. In the cases of FIG. 20(a) and FIG. 20(c), the following configurations are adopted. As in the case of FIG. 11(a), the buried-channel nMOSFET is used for the nMOSFET MN1, and a potential equivalent to a voltage value obtained by resistively dividing the power supply voltage Vdd is applied from the respective resistive potential divider circuits to the body terminal bn1 so that a forward voltage can be applied to the semiconductor junction between the body and the source. More desirably, the resistance values are set so that the forward voltage applied to the semiconductor junction between the body and the source becomes equal to or lower than the diffusion potential of silicon. In the cases of FIG. 20(b) and FIG. 20(d), the following configurations are adopted. As in the case of FIG. 11(b), the buried-channel pMOSFET is used for the pMOSFET MP1, and a potential equivalent to a voltage value obtained by resistively dividing the power supply voltage Vdd is applied from the respective resistive potential divider circuits to the body terminal bp1 so that a forward voltage can be applied to the semiconductor junction between the body and the source. More desirably, the resistance values are set so that the forward voltage applied to the semiconductor junction between the body and the source becomes equal to or lower than the diffusion potential of silicon.

Although each of the foregoing examples of the third embodiment has illustrated the simplest configuration example as the means for resistively is dividing the power supply voltage Vdd to apply a potential to the body terminals, it is also possible to control the potential to be applied to the body region by combining a plurality of resistors and MOSFETs. For example, providing MOS switches between a resistor and the higher potential-side power supply wire and between a resistor and a grounding wire makes it possible to apply a potential to a body terminal and a body region only when necessary.

In addition, it is desirable that when a p-type Si substrate is used, the buried-channel nMOSFET used in the third embodiment is provided with a triple well structure, although not particularly shown in the drawings. Even when a forward voltage is applied to the body terminal of the buried-channel nMOSFET, effects of the voltage application on the other nMOSFETs disposed on the same substrate can be avoided if using the triple well structure.

In the third embodiment, variations occur in the potentials to be applied to the body terminals due to the variations in the resistance values of the resistors that constitute the potential-applying means to the body terminals. For this reason, the second embodiment is superior in that it is free from the variations in the resistance values of resistors (in other words, no resistor is used).

Next, a more detailed simulation was conducted in order to investigate the influence of the low-frequency noise of current source transistors and oscillator transistors on the phase noise characteristic of an oscillator. In the simulation describe below, a Si_{0.70}Ge_{0.30} layer is used as the SiGe channel layer 65 of the SiGe-pMOSFET of FIG. 1(b).

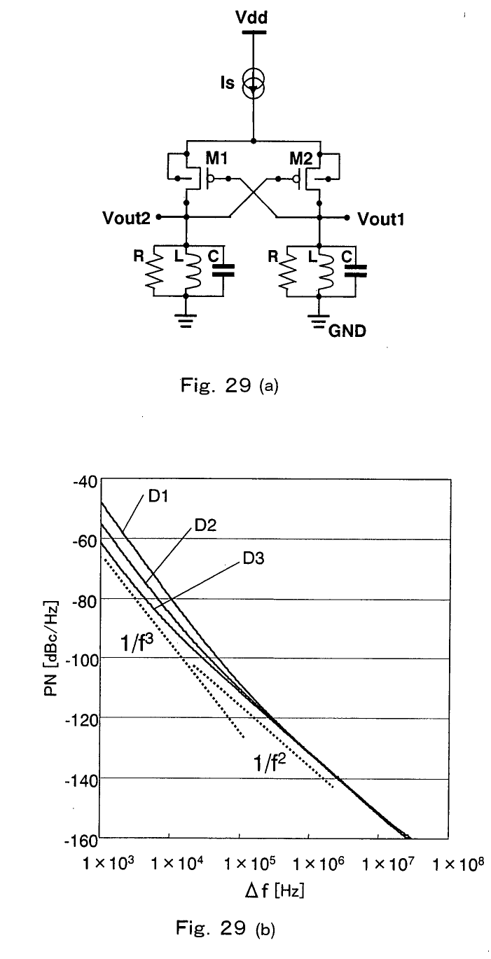

First, a description will be made about a simulation regarding phase noise that was conducted using an ideal current source as the current source of an oscillator. FIG. 29(a) is a circuit diagram of an LC oscillator used for the simulation. The dimensions of both amplifying transistors M1 and M2 were: the gate length was 0.5 μm and the gate width was 100 μm. The power supply voltage Vdd was 3 V, and the current value of the ideal current source Is was set at 6 mA. Two sets of a resistor R, a coil L, and a capacitor C were used for the resonant circuit. The resistance value of the resistor R was 182Ω. The inductance of the coil L was 4 nH. The capacitance of the capacitor C was 3 pF. The oscillation frequency was set at 1.2 GHz. This simulation was conducted for the case in which the conventional surface-channel Si-pMOSFET was used for the transistors M1 and M2, and for the case in which the buried-channel SiGe-pMOSFET shown in FIG. 1(b) was used therefor. Here, the simulation for the buried-channel SiGe-pMOSFET was conducted for the cases in which the body-source voltage Vb was set at 0 V and at −0.6 V.

The results of the simulation are shown in FIG. 29(b). In FIG. 29(b), D1 represents the phase noise PN of the conventional surface-channel Si-pMOSFET for which the body-source voltage Vb was controlled at 0 V, D2 represents the phase noise PN of the SiGe-pMOSFET for which the body-source voltage Vb was set at 0 V, and D3 represents the phase noise PN of the SiGe-pMOSFET for which the body-source voltage Vb was set at −0.6 V. The phase noise PN is defined at the frequency that is an offset frequency Δf away from the desired signal frequency (the oscillation frequency 1.2 GHz herein), so the horizontal axis of FIG. 29(b) represents offset frequency Δf. The influence of the 1/f noise of the transistors appears as the 1/P component, and the influence of the thermal noise (white noise) appears as the 1/f² component. As for the 1/f3 component, the phase noise (D2) of the SiGe-pMOSFET (Vb=0V) is lower by about 8 dBc than the phase noise (D1) of the conventional surface-channel Si-pMOSFET, and the phase noise (D3) of the SiGe-pMOSFET in which a forward voltage is applied between the body and the source (Vb=−0.6V) is even lower by about 15 dBc. It will be appreciated that the phase noise can be lowered by the use of the SiGe-pMOSFET for the amplifier circuit for an oscillator in comparison with the conventional surface-channel Si-pMOSFET, and moreover, the phase noise can be further reduced by applying a forward voltage between the body and the source of that SiGe-pMOSFET. In addition, it will be appreciated that the 1/f² component is little dependent on the types of transistors.

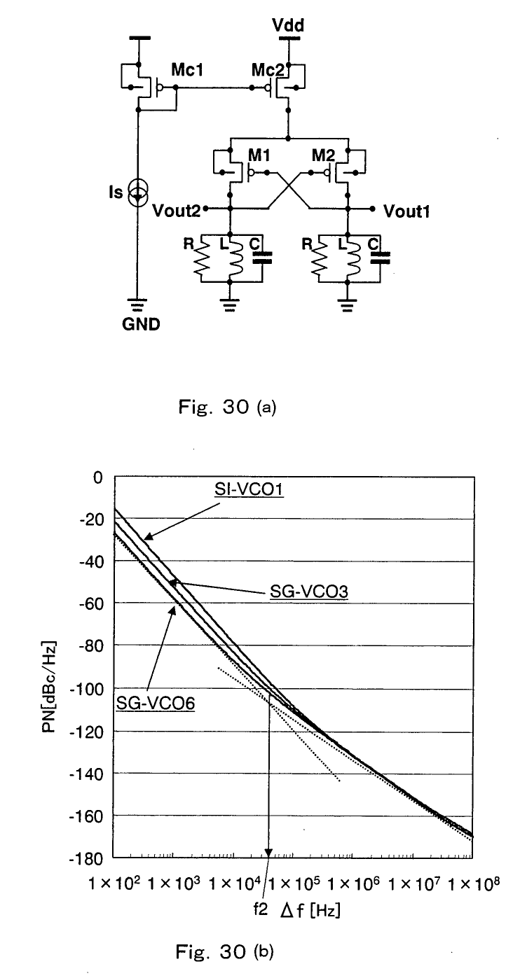

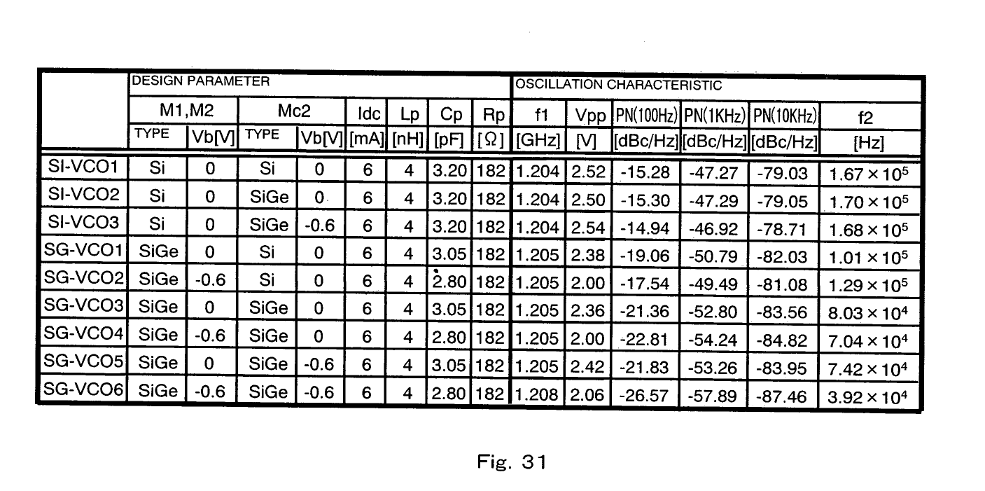

Next, a description will be made about a simulation conducted regarding phase noise by changing the current source of the oscillator to various types. FIG. 30(a) is a circuit diagram of an LC oscillator used for the simulation. A current mirror circuit is constructed using transistors Mc1, Mc2 and an ideal current source Is, and the transistor Mc2, one of the transistors that constitute the current mirror circuit, serves as the current source. Two sets of a resistor R, a coil L and a capacitor C are used for the resonant circuit. Herein, the simulation Was conducted for the case in which the conventional surface-channel Si-pMOSFET was used for each of transistors M1 and M2 for amplification and the transistor Mc2 of the current source in the oscillator, and for the case in which the buried-channel SiGe-pMOSFET shown in FIG. 1(b) is used therefor. In addition, the simulation for the buried-channel SiGe-pMOSFET was conducted for the cases in which the body-source voltage Vb was set at 0 V and −0.6 V. The design parameters that were set in various cases in this simulation and the oscillation characteristics that were obtained by the simulation results are summarized in the table shown in FIG. 31. Among the design parameters shown in FIG. 31, “Si” in the columns of the types of the transistors M1 and M2 for amplification and the transistor Mc2 for the current source indicates the use of the conventional surface-channel Si-pMOSFET, while “SiGe” indicates the use of the buried channel SiGe-pMOSFET. For either type of the transistors, the dimensions of the transistors M1 and M2 for amplification were that the gate length was 0.5 μm and the gate width 100 μm, and the dimensions of the transistor Mc2 for the current source were that the gate length was 1 μm and the gate width was 200 μm. The power supply voltage Vdd was 3 V, and the current value Idc of the transistor Mc2 of the current source was set at 6 mA. The inductance Lp of the coil L was 4 nH, the resistance value Rp of the resistor R was 182Ω, and the capacitance Cp of the capacitor C was as shown in FIG. 31, wherein the coil L, the resistor R and the capacitor C are used for the resonant circuit. In addition, the oscillation characteristics shown in FIG. 31 are oscillation frequency f1, peak oscillation output voltage Vpp, phase noises PN at offset frequencies Δf of 100 Hz, 1 kHz, and 10 kHz, which are the differences from the oscillation frequency, and offset frequency f2 which is a frequency at the boundary between the 1/f³ component and the 1/f² component of the phase noise PN (see FIG. 31 (b)). The phase noise characteristics in the cases of SI-VCO1, SG-VCO3, and SG-VCO6 are shown in FIG. 31(b).

As is appreciated when comparing the case of SI-VCO1 and the case of SI-VCO2 in FIG. 31, little difference is observed in phase noise PN when the transistor Mc2 of the current source is either the conventional surface-channel Si-pMOSFET or the buried channel SiGe-pMOSFET, in the case that the transistors M1 and M2 for amplification are the conventional surface-channel Si-pMOSFETs.

As is appreciated when comparing the case of SI-VCO1 and the case of SI-VCO3 in FIG. 31, the phase noise PN in the case that the buried channel SiGe-pMOSFET is used for the transistor Mc2 of the current source is lower than the phase noise PN in the case that the conventional surface-channel Si-pMOSFET is used therefor, provided that the buried channel SiGe-pMOSFETs is used for the transistors M1 and M2 for amplification.

As is appreciated when comparing the case of SI-VCO2 and the case of SI-VCO4, also with the application of a forward voltage between the body and the source by setting the body-source voltage of each of the transistors M1 and M2 for amplification at −0.6 V, the phase noise PN in the case that the buried channel SiGe-pMOSFET is used for the transistor Mc2 of the current source is lower than the phase noise PN in the case that the conventional surface-channel Si-pMOSFET is used therefor, provided that the transistors M1 and M2 for amplification are the buried channel SiGe-pMOSFETs.

Moreover, as is appreciated when comparing the case of SI-VCO4 and the case of SI-VCO6, provided that the buried-channel SiGe-pMOSFET is used for the transistors M1 and M2 for amplification and the transistor Mc2 of the current source, and the body-source voltage Vb of each of the transistors M1 and M2 for amplification is set at −0.6 V to thereby cause a forward voltage to be applied between the body and the source, the phase noise PN is lowered when the body-source voltage Vb of the transistor Mc2 of the current source is also set at −0.6 V to thereby cause a forward voltage to be applied between the body and the source.

The foregoing simulation results may be summarized as follows. When the buried channel SiGe-pMOSFET is used for the transistors M1 and M2 for amplification and a forward voltage is applied between the body and the source thereof, it is preferable to use the buried channel SiGe-pMOSFET also for the transistor Mc2 of the current source from the point of view of reducing phase noise PN. It is more preferable that a forward voltage is applied also between the body and the source of the buried-channel SiGe-pMOSFETs used for the transistor Mc2 of the current source.

From the foregoing description, numerous improvements and other embodiments of the present invention will be readily apparent to those skilled in the art. Accordingly, the foregoing description is to be construed only as illustrative examples and as being presented for the purpose of suggesting the best mode for carrying out the invention to those skilled in the art. Various changes and modifications can be made in specific structures and/or functions substantially without departing from the scope and spirit of the invention.

### INDUSTRIAL APPLICABILITY

The oscillator according to the present invention is useful for analog high-frequency circuits that require low noise characteristics since the oscillator has low noise characteristics comparable to bipolar transistors and is of low-cost and suitable for integrated circuits, despite being constructed using field-effect transistors.

1. An oscillator comprising:
a first power supply wire; a second power supply wire applied with a power supply voltage between said first power supply wire and said second power supply wire; a resonant circuit; a pair of first and second field-effect transistors, the source regions of which are electrically connected to each other and the drain regions of which are electrically connected to said resonant circuit and mutually differentially connected; and a current source connected between said second power supply wire and a portion where the source regions of said first and second field-effect transistors are electrically connected to each other;
wherein each of said first and second field-effect transistors is a buried channel transistor comprising a body region of a first conductivity type, formed on a semiconductor substrate, the source region and the drain region of a second conductivity type, formed on said body region, a buried channel layer formed between the source region and the drain region, and a gate electrode formed above the buried channel layer with a gate insulating film interposed therebetween, each of said first and second field-effect transistors being provided with a body terminal electrically connected to said body region, and
wherein said oscillator comprises a body potential applying circuit configured to apply a body potential to said body terminal so that a differential voltage between a voltage drop of said current source and a voltage that is between a potential of said second power supply wire and the body potential to be applied to said body terminal is applied, in a forward direction, to a semiconductor junction between said body region and said source region of each of said first and second field-effect transistors, and so that the differential voltage is equal to or lower than a diffusion potential difference of said semiconductor junction.

2. The oscillator according to claim 1, wherein:
the first conductivity type is n type, the second conductivity type is p type, and said first and second field-effect transistors are p-channel field effect transistors;
said first power supply wire is a higher potential-side power supply wire, and said second power supply wire is a lower potential-side power supply wire; and
said body potential applying circuit is a wire that connects said body terminal to said lower potential-side power supply wire.

3. The oscillator according to claim 1, wherein:
the first conductivity type is p type, the second conductivity type is n type, and said first and second field-effect transistors are n-channel field effect transistors;
said first power supply wire is a higher potential-side power supply wire, and said second power supply wire is a lower potential-side power supply wire; and
said body potential applying circuit is a wire that connects said body terminal to said higher potential-side power supply wire.

4. The oscillator according to claim 3, further comprising:
a pair of first and second p-channel field effect transistors differentially connected to each other, each of source regions of said first and second p-channel field effect transistors being electrically connected to said higher potential-side power supply wire and each of drain regions of said first and second p-channel field effect transistors being electrically connected to said resonant circuit; and
wherein each of said first and second p-channel field effect transistors is a buried channel transistor comprising an n-type body region formed on said semiconductor substrate, said source region and said drain region of p-type formed on said body region, a buried channel layer formed between said source region and said drain region, and a gate electrode formed above said buried channel layer with a gate insulating film interposed therebetween, said buried channel transistor being provided with a body terminal electrically connected to said body region, and said body terminal is connected to said lower potential-side power supply wire; and
wherein said power supply voltage is applied in a forward direction to the semiconductor junction between the body region and the source region of each of said first and second p-channel field effect transistors, and is equal to or lower than the diffusion potential difference of the semiconductor junction.

5. The oscillator according to claim 1, wherein:
the first conductivity type is n-type, the second conductivity type is p-type, and said first and second field-effect transistors are p-channel field effect transistors;
said first power supply wire is a lower potential-side power supply wire, and said second power supply wire is a higher potential-side power supply wire; and
said body potential applying circuit is a circuit connected between said higher potential-side power supply wire and said lower potential-side power supply wire, and configured to apply, as the body potential, a potential equivalent to a divided voltage of the power supply voltage to said body terminal.

6. The oscillator according to claim 1, wherein:
the first conductivity type is p type, the second conductivity type is n type, and said first and second field-effect transistors are n-channel field effect transistors;
said first power supply wire is a higher potential-side power supply wire, and said second power supply wire is a lower potential-side power supply wire; and
said body potential applying circuit is a circuit configured to apply, as the body potential, a potential equivalent to a divided voltage of the power supply voltage to said body terminal.

7. The oscillator according to claim 6, further comprising:
a pair of first and second p-channel field effect transistors differentially connected to each other, each of source regions of said first and second p-channel field effect transistors being electrically connected to said higher potential-side power supply wire and each of drain regions of said first and second p-channel field effect transistors being electrically connected to said resonant circuit; and
wherein each of said first and second p-channel field effect transistors is a buried channel transistor comprising an n-type body region formed on said semiconductor substrate, said source region and said drain region of p-type formed on said body region, a buried channel layer formed between said source region and said drain region, and a gate electrode formed above said buried channel layer with a gate insulating film interposed therebetween, each of said first and second p-channel field effect transistors being provided with a body terminal electrically connected to said body region; and
wherein said oscillator further comprises a voltage divider circuit connected between said higher potential-side power supply wire and said lower potential-side power supply wire and configured to, apply a potential equivalent to a divided voltage of the power supply voltage to said body terminal of each of said first and second p-channel field effect transistors; and
wherein a differential voltage between a potential of said higher potential-side power supply wire and a potential applied by the voltage divider circuit to said body terminal of each of said first and second p-channel field effect transistors is applied, in a forward direction, to the semiconductor junction between said body region and said source region of each of said first and second field-effect transistors, and the differential voltage is equal to or lower than a diffusion potential difference of said semiconductor junction.

8. The oscillator according to claim 2, wherein the semiconductor substrate is composed mainly of silicon, and the buried channel layer of the p-channel field effect transistor is formed of a SiGe layer or a SiGeC layer.

9. The oscillator according to claim 3, wherein the semiconductor substrate is composed mainly of silicon, and the buried channel layer of the n-channel field effect transistor is formed of a SiC layer or a SiGeC layer.

10. The oscillator according to claim 4, wherein the semiconductor substrate is composed mainly of silicon, and the buried channel layer of the p-channel field effect transistor is formed of a SiGe layer or a SiGeC layer, and the buried channel layer of the n-channel field effect transistor is formed of a SiC layer or a SiGeC layer.

11. The oscillator according to claim 8, wherein a distance from said gate insulating film to said buried channel layer is longer than 0 nm and shorter than 5 nm.

12. The oscillator according to claim 8, wherein a distance from said gate insulating film to said buried channel layer is longer than 0.5 nm and shorter than 3 nm.

13. The oscillator according to claim 5, wherein the semiconductor substrate is composed mainly of silicon, and the buried channel layer of the p-channel field effect transistor is formed of a SiGe layer or a SiGeC layer.

14. The oscillator according to claim 6, wherein the semiconductor substrate is composed mainly of silicon, and the buried channel layer of the n-channel field effect transistor is formed of a SiC layer or a SiGeC layer.

15. The oscillator according to claim 7, wherein the semiconductor substrate is composed mainly of silicon, and the buried channel layer of the p-channel field effect transistor is formed of a SiGe layer or a SiGeC layer, and the buried channel layer of the n-channel field effect transistor is formed of a SiC layer or a SiGeC layer.

16. The oscillator according to claim 9, wherein a distance from said gate insulating film to said buried channel layer is longer than 0 nm and shorter than 5 nm.

17. The oscillator according to claim 10, wherein a distance from said gate insulating film to said buried channel layer is longer than 0 nm and shorter than 5 nm.

18. The oscillator according to claim 9, wherein a distance from said gate insulating film to said buried channel layer is longer than 0.5 nm and shorter than 3 nm.

19. The oscillator according to claim 10, wherein a distance from said gate insulating film to said buried channel layer is longer than 0.5 nm and shorter than 3 nm.
